(19) United States
(12) Patent Application Publication
(10) Pub. No.: US 2017/0207415 A1
(43) Pub. Date: Jul. 20, 2017

(54) GAS BARRIER FILM AND ORGANIC ELECTROLUMINESCENT ELEMENT

(71) Applicant: KONICA MINOLTA, INC., Tokyo (JP)

(72) Inventor: Hiromoto II, Machida-shi, Tokyo (JP)

(21) Appl. No.: 15/327,751

(22) PCT Filed: Aug. 10, 2015
(86) PCT No.: PCT/JP2015/072665

§ 371 Date: Jan. 20, 2017

(30) Foreign Application Priority Data
Sep. 10, 2014 (JP) 2014-184371

(51) Int. Cl. H01L 51/52; H01L 51/50; B32B 27/06

(52) U.S. Cl. CPC H01L 51/5253; B32B 27/06; H01L 51/5206; H01L 51/5221; H01L 51/5012; B32B 2307/7242; B32B 2309/105; B32B 2457/206; B32B 2310/0831; H01L 2251/533; H01L 2251/558; H01L 2251/301

(57) ABSTRACT

Provided is a gas barrier film which has sufficient gas barrier properties, while using a resin base of 50 μm or less. This gas barrier film is configured to comprise: a resin base having a thickness of 3-50 μm; a first gas barrier layer containing an inorganic compound; a second gas barrier layer that is formed by applying an energy to a coating film, which is obtained by applying and drying a coating liquid containing a polysilazane, and has a region satisfying a composition range represented by SiOwNx (wherein 0.2<w≦0.55 and 0.66<x≦0.75) and having a thickness of 50-1,000 nm; and a third gas barrier layer that is formed in contact with the second gas barrier layer and contains, as a main component, an oxide of a metal that has a lower redox potential than silicon.

### TECHNICAL FIELD

The present invention relates to a gas barrier film, and an organic electroluminescent element using the gas barrier film.

### BACKGROUND ART

An organic electroluminescent element utilizing electroluminescence (hereinafter, simply referred to as “EL”) of an organic material is a thin-film-type completely solid-state element that can emit light at a low voltage of approximately several volts to several ten volts, and has many excellent advantages such as high luminance, high light-emission efficiency, thin type and light weight. Accordingly, especially in recent years, an organic EL element using a gas barrier film having a gas barrier layer on a resin base of thin type and light weight has attracted attention as surface emitting bodies such as: backlights for various kinds of displays; display boards for signboards, emergency lights and the like; and lighting sources.

As such a gas barrier film used for the organic EL element, there has been proposed, for example, a gas barrier film having a layer in which an ion of a hydrocarbon-based compound is injected into a layer containing a polysilazane compound on a base (for example, referring to Patent Literature 1). Furthermore, there has been proposed a gas barrier film having a silicon-containing film which has a high nitrogen concentration region formed on a base (for example, refer to Patent Literature 2). Furthermore, there has been proposed a gas barrier film in which a polysilazane modified film is used (for example, refer to Patent Literature 3).

### CITATION LIST

### Patent Literature

PTL 1: WO2011/122547

PTL 2: WO2011/007543

PTL 3: Japanese Patent Laid-Open No. 2014-94572

### SUMMARY OF INVENTION

Technical Problem

However, even in the organic EL element in which the above gas barrier film is used, the generation of dark spots cannot be suppressed sufficiently when storing the element for a long period under a high temperature and high humidity circumstance of 85° C. and 85% RH. Particularly, when using a resin base having a thin film of 50 μm or less, a gas barrier property is not sufficient.

In order to solve the above problems, the present invention provides a gas barrier film having sufficient gas barrier properties, and a highly reliable organic electroluminescent element using the gas barrier film, on a resin base of 50 μm or less.

Solution to Problem

The gas barrier film of the present invention includes: a resin base having a thickness of 3 to 50 μm; a first gas barrier layer containing an inorganic compound; a second gas barrier layer that is formed by applying an energy to a coating film obtained by applying and drying a coating liquid containing a polysilazane, and that has a region satisfying a composition range represented by SiO_{w}Nₓ (wherein 0.2<w≦0.55 and 0.66<x≦0.75) and having a thickness of 50 to 1,000 nm; and a third gas barrier layer that is formed in contact with the second gas barrier layer and that contains, as a main component, an oxide of a metal that has a lower redox potential than silicon.

Furthermore, the organic electroluminescent element of the present invention includes the above-described gas barrier film, and an organic functional layer sandwiched between a first electrode and a second electrode.

Advantageous Effects of Invention

According to the present invention, it is possible to provide a gas barrier film having sufficient gas barrier properties, and an organic electroluminescent element having a high reliability.

### BRIEF DESCRIPTION OF DRAWINGS

FIG. 1 shows a configuration of a gas barrier film according to an embodiment.

FIG. 2 shows one example of a film deposition apparatus that fabricates a first gas barrier layer.

FIG. 3 shows one example of the film deposition apparatus that fabricates the first gas barrier layer.

FIG. 4 shows a configuration of an organic electroluminescent element according to the embodiment.

### DESCRIPTION OF EMBODIMENTS

Hereinafter, examples of the embodiments for carrying out the present invention will be explained, but the present invention is not limited the following examples.

The explanation will be done in the following order.
1. Embodiment of gas barrier film
2. Embodiment of organic electroluminescent element

### <1. Embodiment of Gas Barrier Film>

Hereinafter, the embodiment of gas barrier film will be explained.

FIG. 1 shows a schematic configuration view of the gas barrier film according to the present embodiment. The gas barrier film shown in FIG. 1 is constituted of a resin base 1, and a gas barrier layer 22 which is formed on the resin base 1. The gas barrier layer 22 is constituted by including a lamination structure in which a gas barrier layer 22a, a second gas barrier layer 22b, and a third gas barrier layer 22c are laminated from the resin base 1 side in this order.

The resin base 1 is a thin resin film having flexibility and a thickness of 3 to 50 μm. The first gas barrier layer 22a is constituted by containing an inorganic compound. The second gas barrier layer 22b is formed by applying an energy to a coating film obtained by applying and drying a coating liquid which contains a polysilazane. In addition, the second gas barrier layer 22b has a region satisfying a composition range represented by SiO_{w}Nₓ (wherein 0.2<w≦0.55 and 0.66<x≦0.75) and having a thickness of 50 to 1,000 nm. The third gas barrier layer 22c is formed in contact with the second gas barrier layer 22b and contains, as a main component, an oxide of a metal that has a lower redox potential than silicon.

In a case of applying a thin resin base of 50 μm or less to the organic EL element, gases from the outside such as moisture and oxygen, which are toxic to the organic EL element, become easily intruded into a conventional thick resin base. Accordingly, from the viewpoints of preventing the intrusion of these gases from the outside and enhancing the stability and the durability of the organic EL element, it becomes necessary to enhance an ability of the gas barrier layer that suppresses the intrusion of the outside.

In addition, the thin resin base has slight difficulties in flatness (surface smoothness) in comparison with the conventional thick resin base, and thus, when a transparent electrode is directly formed thereon, the smoothness of the transparent electrode is affected since the surface unevenness pattern of the thin resin base is reflected to the transparent electrode as it is.

In order to cope with such problems, it is possible to form a transparent electrode having a high smoothness by forming the gas barrier layer 22 on the resin base 1. Particularly, it is possible to form a transparent electrode having a high smoothness by including the second gas barrier layer 22b which satisfies the above-described composition range. The second gas barrier layer 22b can be formed by, for example, a wet coating method and a surface modification treatment. Specifically, it is possible to fabricate the second gas barrier layer 22b by: forming a gas barrier forming precursor layer through the use of a polysilazane coating liquid; smoothing the unevenness of the resin base by the gas barrier forming precursor layer; and then subjecting the surface to the modification treatment by radiating energy such as vacuum ultraviolet ray to the surface.

In addition, it becomes unnecessary to expose the thin resin base to a high temperature circumstance in comparison with a sputtering method or the like, by formation of the second gas barrier layer 22b through the use of the above wet coating method and the surface modification treatment. Furthermore, when the modification treatment is carried out from the surface of the gas barrier forming precursor layer, the modification treatment of the surface side proceeds and thus the surface side becomes a hard film. On the other hand, since the modification treatment of the lower side does not proceed completely, the lower side becomes a soft film to some extent, and it is possible to impart a film hardness distribution within the gas barrier layer 22.

As a result, a soft lower portion of the gas barrier layer having a relatively large displacement amount is arranged on the resin base side having a large elongation, and a hard surface portion gas barrier layer in which the modification proceeds is arranged on the transparent electrode side having a small elongation. As the result, the response to the change of the external circumstance becomes smooth, the concentration of stress to the specified region can be prevented, and thus there can be obtained a gas barrier film having excellent durability (elongation resistance).

The second gas barrier layer 22b exhibits the gas barrier property when having the region where the above composition range represented by SiO_{w}Nₓ is satisfied (hereinafter, also simply referred to as region (b)). Moreover, the second gas barrier layer 22b is not formed by a vapor deposition method, but is formed by applying an energy to the coating film which is obtained by applying and drying the coating liquid containing the polysilazane. Therefore, contamination by foreign substances such as particles is not almost generated at the time of film deposition, and thus it becomes possible to form a layer having extremely few defects.

However, the region (b) of the second gas barrier layer 22b is not completely stable against the oxidation, and there is a case where the gas barrier property becomes lowered due to gradual oxidation under the high temperature and high humidity circumstance. For example, when water vapor is locally leaked from the resin base 1 side, the second gas barrier layer 22b is locally oxidized by the water vapor to thereby form a portion where the gas barrier property is lowered. When water vapor is intruded through the portion where the gas barrier property is lowered, it is considered that dark spots will be generated in the organic EL element.

Therefore, in the gas barrier film having the above configuration, the third gas barrier layer 22c is formed in contact with the second gas barrier layer 22b. The third gas barrier layer 22c contains, as a main component, an oxide of a metal that has a lower redox potential than silicon. It is considered that the gas barrier property of the third gas barrier layer 22c itself is not so high, and the third gas barrier layer 22c does not have the gas barrier property to the extent of contributing to the lowering of the dark spots of the organic EL element.

However, since the third gas barrier layer 22c contains, as a main component, an oxide of a metal that has a low redox potential, the third gas barrier layer is oxidized earlier than the region (b) of the second gas barrier layer 22b under the high temperature and high humidity circumstance. Therefore, when the third gas barrier layer 22c is formed in contact with the second gas barrier layer 22b, the suppression effect of the oxidation of the surface of the second gas barrier layer 22b under the high temperature and high humidity circumstance is exhibited, and thus the local lowering of the gas barrier property is difficult to be generated. It is assumed that, since the lowering of the gas barrier property due to the composition of the second gas barrier layer 22b can be suppressed by the third gas barrier layer 22c as described above, the durability of the gas barrier film having the above-described configuration under the high temperature and high humidity circumstance can be enhanced.

Accordingly, the above gas barrier film having the gas barrier layer 22 constituted by the first gas barrier layer 22a, the second gas barrier layer 22b and the third gas barrier layer 22c is excellent in durability under the high temperature and high humidity circumstance of 85° C. and 85% RH, and when the resin base 1 having a thin film of 50 μm or less is used, sufficient gas barrier property can be obtained. Here, although the detailed mechanism in which the high gas barrier property is exhibited in the above gas barrier film is not clear, the above-described mechanism is speculated. Note that the above mechanism is a speculation, and the exhibition of the gas barrier property of the gas barrier film is not restricted to the above mechanism.

Hereinafter, each configuration of the gas barrier film will be explained. Note that, in the following explanation, the size ratio in the drawings may be exaggerated from the explanation point of view, there is a case where the size ratio in the drawings is different from the real size ratio. Further, Hereinafter explanation, the operation and measurement of physical properties and the like are conducted under the conditions of room temperature (20 to 25° C.)/relative humidity 40 to 50%, otherwise noted.

### [Resin Base]

The resin base 1 constituting the gas barrier film is a flexible resin film that can be bended and has flexibility, and is a thin resin having a thickness within the range of 3 to 50 μm. The resin base 1 is not particularly limited as long as the material is a resin material that can hold each structural layer described below.

Examples of the resin bases 1 include: polyesters such as polyethylene terephthalate (abbreviation: PET) and polyethylene naphthalate (abbreviation: PEN); polyethylene; polypropylene; cellulose esters or derivative thereof such as cellophane, cellulose diacetate, cellulose triacetate (abbreviation: TAC), cellulose acetate butylate, cellulose acetate propionate (abbreviation: CAP), cellulose acetate phthalate and cellulose nitrate; polyvinylidene chloride; polyvinyl alcohol; polyethylene vinyl alcohol; syndiotactic polystyrene; polycarbonate (abbreviation: PC); norbornen resin; polymethylpenten; polyether ketone; polyimide; polyether sulphone (abbreviation: PES); polyphenylene sulfide; polysluphones; polyether imide; polyether ketone imide; polyamide; fluoro resin; Nylon; polymethyl methacrylate; acrylics or polyallylates; cycloolefins-based resin such as Alton (commercial name of JSR) or APEL (commercial name of Mitsui Chemicals), and the like.

Among these resin bases 1, from the viewpoints of cost and availability, a film such as polyethylene terephthalate (abbreviation: PET), polybutylene terephthalate, polyethylene naphthalate (abbreviation: PEN), or polycarbonate (abbreviation: PC) is preferably used as a flexible resin.

The thickness of the resin base 1 is within the range of 3 to 50 μm, preferably 3 to 35 μm, more preferably 3 to 30 μm, and particularly preferably 10 to 30 μm.

The resin base 1 is preferably made of a material having heat resistance. Specifically, there is used a resin having a linear expansion coefficient of 15 ppm/K or more and 100 ppm/K or less, and a glass transition temperature (Tg) of 100° C. or more and 300° C. or less. The resin base 1 satisfies the requirements for uses of electronic parts and a laminated film for display. Namely, in a case where the gas barrier film is used for these use applications, the gas barrier film may be exposed to a step of 150° C. or more. In this case, when the linear expansion coefficient of the resin base 1 of the gas barrier film exceeds 100 ppm/K, there is easily caused inconvenience that the size of the substrate is not stable in causing the gas barrier film to flow through the step of the above temperature, the insulation performance is deteriorated due to the thermal expansion and shrinkage, or there is easily caused troubles that the film cannot withstand a thermal step. When the linear expansion coefficient is less than 15 ppm/K, the film is broken like a glass and its flexibility is lowered.

The Tg and linear expansion coefficient of the resin base 1 can be adjusted by an additive, and the like. Specific examples of more preferable thermoplastic resin used as the resin base 1 include polyethylene terephthalate (PET: 70° C.), polyethylene naphthalate (PEN: 120° C.), polycarbonate (PC: 140° C.), alicyclicpolyolefin (for example, ZEONOR (registered trademark) 1600 manufactured by Zeon Corporation.: 160° C.) polyarylate (PAr: 210° C.), polyether sulfone (PES: 220° C.), polysulfone (PSF: 190° C.), a cycloolefin copolymer (COC: the compound disclosed in Japanese Patent Laid-Open No. 2001-150584: 162° C.), polyimide (for example, Neo Prim (registered trademark) manufactured by Mitsubishi Gas Chemical Company, Inc.: 260° C.), fluorene ring-modified polycarbonate (BCF-PC: the compound disclosed in Japanese Patent Laid-Open No. 2000-227603: 225° C.), alicyclic-modified polycarbonate (IP-PC: the compound disclosed in Japanese Patent Laid-Open No. 2000-227603: 205° C.), and an acryloyl compound (the compound disclosed in Japanese Patent Laid-Open No. 2002-80616: 300° C. or more), and the like, (the parenthesis represents Tg).

Furthermore, when the gas barrier film is arranged at the light extraction side of the electronic device such as the organic EL element, the resin base 1 is preferably transparent. Transparency means that a light transmittance is 80% or more, preferably 85% or more, further preferably 90% or more. The light transmittance can be calculated in accordance with the method described in JIS-K 7105: 1981, namely, by measuring a whole light transmittance and an amount of scattered light through the use of an integrated-sphere-type light transmittance measuring device, and by subtracting a diffusion transmittance from the whole light transmittance. When the resin base 1 is transparent and the respective layers including the transparent electrode formed on the resin base 1 have also similarly a high light transmittance, the light extraction from the resin base 1 side becomes possible. The resin base 1 can be suitably used as a sealing member (transparent substrate) of the organic EL element. In addition, the above resin base 1 may be an un-stretched film, or a stretched film.

The resin base 1 can be produced by a well-known ordinary film deposition method. For example, it is possible to produce an un-stretched resin base 1 which is substantially amorphous and not oriented, by melting resins serving as a material through an extruder, extruding the resins through a circular die or a T die, and then performing rapid cooling. Furthermore, it is possible to produce a stretched resin base, by stretching the un-stretched resin in the resin transporting direction (vertical-axis direction: MD direction) or perpendicular to the resin transporting direction (horizontal-axis direction: TD direction) according to a conventional method such as uniaxial stretching, tenter system sequential biaxial stretching, tenter system simultaneous biaxial stretching, or tubular system simultaneous biaxial stretching. In this case, it is possible to select a stretching magnification depending on resins serving as the raw material for the resin base 1, the ratio is preferably within the range of 2 to 10 times in the vertical direction and in the horizontal direction.

Moreover, the surface of the resin base 1 maybe subjected to a hydrophilic treatment such as a corona treatment before the formation of the polysilazane layer or the like that is a precursor thereof, at the time when the gas barrier layer 22 is formed.

In the method for producing the gas barrier film, from the viewpoint that a thickness of a resin base 1 is 3 to 50 μm, deformation, bending or the like of the resin base is easily generated during the production process and thus it is difficult to handle the resin base 1. When each structural layer is formed on the resin base 1, it is important to maintain a high flatness at a certain position, and thus it becomes necessary to apply tension from the both sides of the transparent base. However, since the transparent base is thin and has insufficient rigidity, position displacement and winkles are generated, and it becomes difficult to accurately and uniformly form a layer.

From the above point of view, it is preferable to apply a support film to the resin base 1. The support film is used at the time of production of the flexible gas barrier film. Examples of the resin material which can be applied as the support film can include the above-described various resin films used for the resin base 1.

A thickness of the support film is not particularly limited, and in consideration of mechanical strength, handling property, and the like, the thickness is preferably 50 to 300 μm. Note that the thickness of the support film can be measured by the use of a micrometer.

The method for fitting the support film to the resin base 1 includes: a method in which an adhesive layer is formed between the resin base 1 and the support film, and pressed by a nip roller or the like to thereby closely adhere to each other; and a method in which, after the resin base 1 and the support film are laminated, the both films are closely adhered by applying a potential difference between the both films under vacuum to thereby electrically charge them. The method for closely adhering films by electrically charging is a method in which the both films are charged with charges opposite to each other to thereby closely adhere the both films electrostatically, and after the various electronic devices are produced on the gas barrier film, the support film is peeled off from the gas barrier film by removing the charge in the discharging step.

### [First Gas Barrier Layer]

The gas barrier film has the first gas barrier layer 22a which contains an inorganic compound on the resin base 1. When the first gas barrier layer 22a is provided, the intrusion of water vapor from the resin base 1 side can be blocked and there is obtained the gas barrier film having the enhanced durability under the high temperature and high humidity circumstance. The first gas barrier layer 22a maybe a single layer or a lamination structure of two or more layers. In a case where the first gas barrier layer 22a is the lamination structure having two or more layers, each first gas barrier layer 22a may have the same composition, or may have different composition.

The first gas barrier layer 22a contains an inorganic compound. The inorganic compound contained in the first gas barrier layer 22a is not particularly limited, and examples include silicon, an oxide of a metal having a higher redox potential than silicon, a metal nitride, a metal carbide, a metal oxynitride, or a metal oxycarbide. Among them, from the viewpoint of the gas barrier performance, it is preferable to use an oxide, a nitride, a carbide, an oxynitride, or an oxycarbide, including one or more of the metals selected from Si, In, Sn, Zn, Cu, and Ce. Examples of the suitable inorganic compound include silicon oxide, silicon nitride, silicon oxynitride silicon carbide, and silicon oxycarbide. Other elements may be included as an auxiliary component.

The content of the inorganic compound contained in the first gas barrier layer 22a is not particularly limited, and is preferably 50% by mass or more relative to the whole mass of the first gas barrier layer 22a, more preferably 80% by mass or more, further preferably 95% by mass or more, particularly preferably 98% by mass or more, and most preferably 100% by mass (namely, the first gas barrier layer 22a is an inorganic compound).

The thickness of the first gas barrier layer 22a (total thickness when the first gas barrier layer has the lamination structure having two or more layers) is not particularly limited and is preferably 5 to 1, 000 nm, more preferably 20 to 500 nm. When the thickness is within the range, there is an advantage that both of productivity and gas barrier property can be obtained. The thickness of the first gas barrier layer 22a can be measured by THM observation.

As the method for forming the first gas barrier layer 22a, there are a method in which energy is applied to a coating film obtained by applying and drying a coating liquid which contains a polysilazane (wet coating system and surface modification treatment), and a vapor deposition method. Among them, the layer is preferably formed by the vapor deposition method that is difficult to be oxidized by humidity and can exhibit the gas barrier property stably under the high temperature and high humidity circumstance.

### (Wet Coating System and Surface Modification Treatment)

In the method in which energy is applied to a coating film obtained by applying and drying a coating liquid which contains a polysilazane which is one of the methods for forming the first gas barrier layer 22a, since the formation conditions (kind of the polysilazane to be used, solvent used for the coating liquid, concentration of the coating liquid, kind of catalyst, and the like) other than the application conditions of energy will be explained in the following explanation as to the second gas barrier layer 22b, here the explanations thereof are omitted. Preferred method for applying energy is due to conversion reaction by a plasma treatment and an ultraviolet ray irradiation treatment which can realize conversion reaction, and more preferable is a method of radiation of a vacuum ultraviolet ray.

The first gas barrier layer 22a formed by applying an energy to the coating film obtained by applying and drying a coating liquid which contains a polysilazane so as to be in contact with the resin base 1 having no gas barrier property, has an oxidized composition, namely SiO_{2.0-2.4} at the resin base 1 side in the thickness direction due to influence of water vapor and oxygen which are permeated from the resin base 1 side. On the other hand, the composition at the surface of the layer where the energy is applied is a SiON wherein, relative to Si, N is about 0.6 or less, and O is about 0.6 or more, and the region has a high gas barrier property and, at the same time, has a better oxidation resistance under the high temperature and high humidity circumstance than the region (b) of the second gas barrier layer 22b. In addition, the first gas barrier layer 22a has an apparent interface on the resin base 1 side and the surface side. Furthermore, the region (b) of the second gas barrier layer 22b is not formed in the first gas barrier layer 22a due to the diffusion of water from the resin base 1.

### (Vapor Deposition Method)

Examples of the vapor deposition methods that are preferable methods for forming the first gas barrier layer 22a include a physical vapor deposition method (PVD method) or a chemical vapor deposition method (CVD method). Hereinafter, the vapor deposition method will be explained.

The physical vapor deposition method (PVD method) is a method in which a desired substance, for example, a thin film such as a carbon film is deposited by physical procedures on a surface in a gas phase, and examples include a sputtering method (DC sputtering method, RF sputtering method, ion beam sputtering method, magnetron sputtering method, and the like), a vacuum vapor deposition method, an ion plating method, and the like.

The chemical vapor deposition method (CVD method) is a method in which a desired thin film is deposited on a base by supplying a gas material which contains a component of the desired thin film to generate a chemical reaction on the surface of the base or in the gas phase. In addition, there is also a method in which plasma or the like is generated in order to activate the chemical reaction, and examples include a known CVD method such as a thermal CVD method, a catalytic chemical vapor deposition method, a light CVD method, a vacuum plasma CVD method or an atmospheric pressure plasma CVD method, and the like. From the viewpoints of vapor-deposition rate and treatment area, the plasma CVD method such as the vacuum plasma CVD method or the atmospheric pressure plasma CVD method is preferably applied, but is not limited.

For example, when a silicon compound is used as a raw compound and oxygen is used as a decomposition gas, an oxide of silicon is generated. This is because, since very active charged particles and active radicals exist in a high density in the plasma field to thereby accelerate multi-stage chemical reactions at very high speed in the plasma field, the elements in the plasma field are converted to a thermodynamically stable compound in an extremely short time.

Hereinafter, a case where the opposed roll-type roll-to-roll film deposition apparatus for forming by the plasma CVD method will be explained as one example of the method for forming the first gas barrier layer 22a by the vapor deposition method.

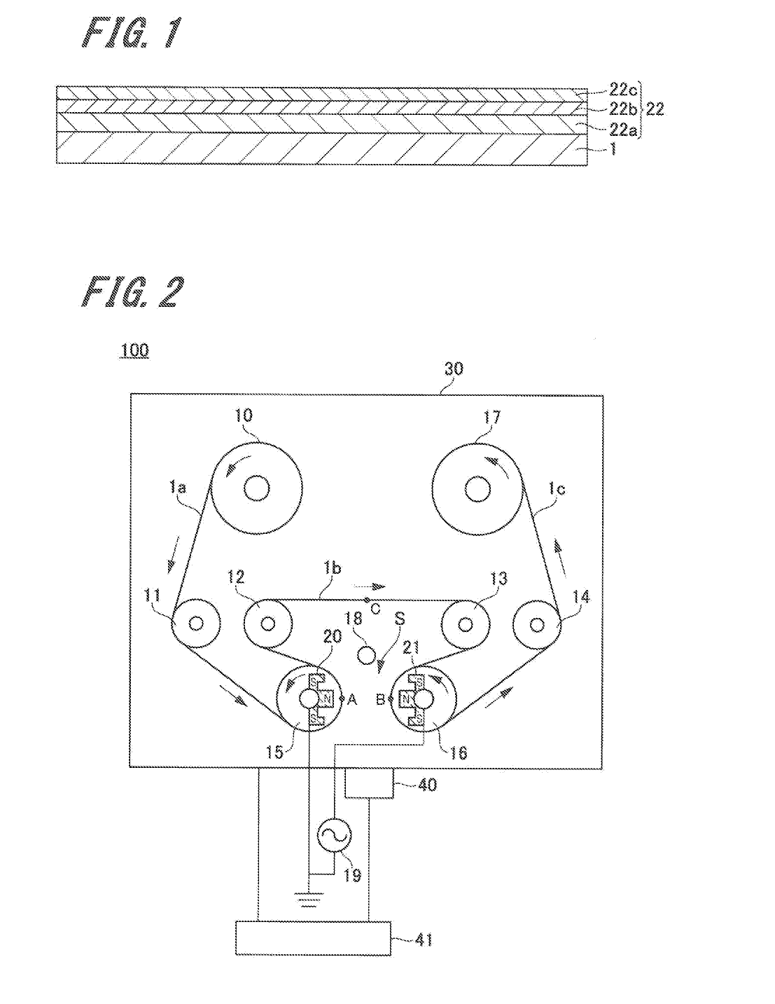

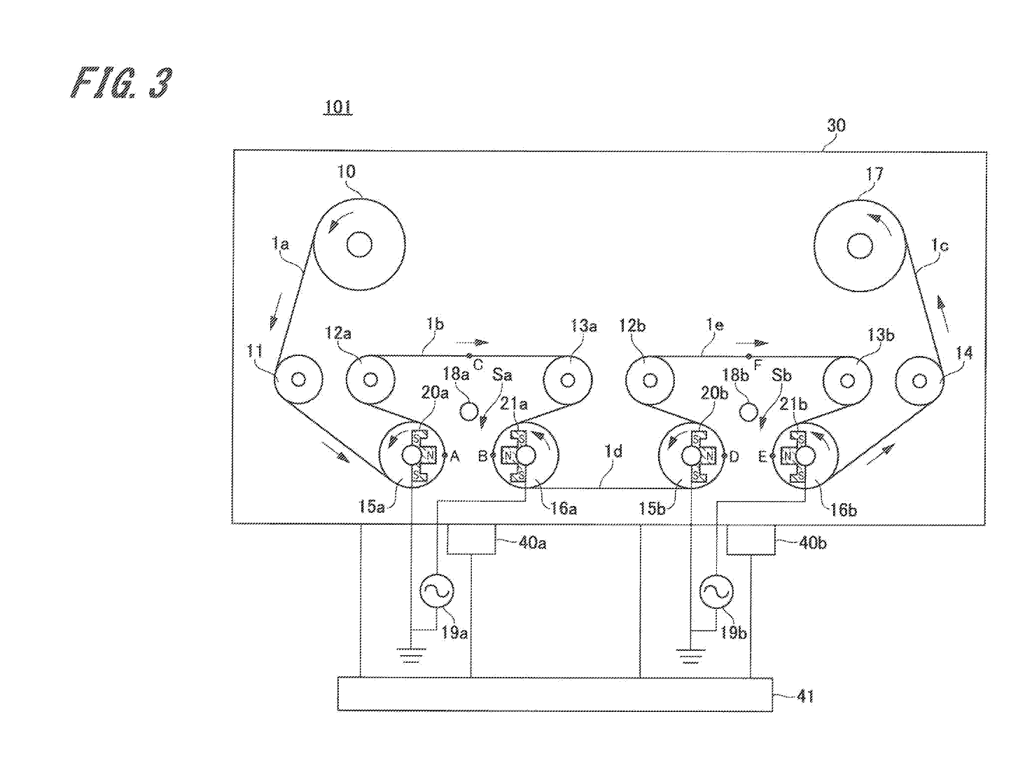

FIG. 2 and FIG. 3 show schematic configuration views of one example of the film deposition apparatus. A film deposition apparatus 101 shown in FIG. 3 is based on a configuration in which two of the film deposition apparatus 100 shown in FIG. 2 are connected. Here, there will be explained a case of forming the first gas barrier layer 22a by taking the film deposition apparatus 101 as an example. The explanation as to the film deposition apparatus 101 shown in FIG. 3 is properly taken into consideration with regard to the explanation as to the film deposition apparatus 100 shown in FIG. 2.

As shown in FIG. 3, the film deposition apparatus 101 includes a feeding roll 10, conveying rolls 11, 12a, 12b, 13a, 13b, and 14, a first film deposition roll 15a, a second film deposition roll 16a, a third film deposition roll 15b, a fourth film deposition roll 16b, a winding roll 17, gas supply pipes 18a and 18b, power sources 19a and 19b for generating plasma, magnetic field-generating devices 20a, 21a, 20b, and 21b, a vacuum chamber 30, vacuum pumps 40a and 40b, and a control portion 41.

The vacuum chamber 30 accommodates the feeding roll 10, the conveying rolls 11, 12a, 12b, 13a, 13b, and 14, the first film deposition roll 15a, the second film deposition roll 16a, the third film deposition roll 15b, the fourth film deposition roll 16b, and the winding roll 17.

The feeding roll 10 feeds a base 1a placed in a previously wound-up state, toward the conveying roll 11. The feeding roll 10 is a cylindrical roll that extends in the perpendicular direction to the paper surface, and feeds the base 1a toward the conveying roll 11 by rotating in the counter-clockwise rotation (see the arrow in FIG. 3) by a driving motor not shown.

The conveying rolls 11, 12a, 12b, 13a, 13b, and 14 are cylindrical rolls constituted so as to be rotatable around a rotation axis approximately parallel to that of the feeding roll 10. The conveying roll 11 is a roll for conveying the base 1a from the feeding roll 10 to the first film deposition roll 15a while giving an appropriate tension to the base 1a. The conveying rolls 12a and 13a are rolls for conveying a base 1b that is film-deposited on the first film deposition roll 15a from the first film deposition roll 15a to the second film deposition roll 16a while giving an appropriate tension to the base 1b. The conveying rolls 12b and 13b are rolls for conveying a base 1e that is deposited on the third film deposition roll 15b from the third film deposition roll 15b to the fourth film deposition roll 16b while giving an appropriate tension to the base 1e. Furthermore, the conveying roll 14 is a roll for conveying a base 1c that is deposited on the fourth film deposition roll 16b from the fourth film deposition roll 16b to the winding roll 17 while giving an appropriate tension to the base 1c.

The first film deposition roll 15a and the second film deposition roll 16a are a pair of film deposition rolls that have rotation axes approximately parallel to that of the feeding roll 10, and that are arranged so as to face each other while being apart from each other at a given distance. Moreover, the third film deposition roll 15b and the fourth film deposition roll 16b are also a pair of deposition rolls that have rotation axes approximately parallel to that of the feeding roll 10, and are arranged so as to face each other while being apart from each other at a given distance. The second film deposition roll 16a deposits the base 1b and conveys the deposited base 1d to the third film deposition roll 15b while giving an appropriate tension to the base 1d. The fourth film deposition roll 16b deposits the base 1e and conveys the deposited base 1c to the conveying roll 14 while giving an appropriate tension to the base 1c.

In the example shown in FIG. 3, the separation distance between the first film deposition roll 15a and the second film deposition roll 16a is a distance between the point A and the point B, and the separation distance between the third film deposition roll 15b and the fourth film deposition roll 16b is a distance between the point D and the point E. The first film deposition roll 15a, the second film deposition roll 16a, the third film deposition roll 15b and the fourth film deposition roll 16b are discharge electrodes made of an electric conductive material, and the first film deposition roll 15a and the second film deposition roll 16a are electrically insulated from each other, and the third film deposition roll 15b and the fourth film deposition roll 16b are electrically insulated from each other. Note that the materials and configurations of the first film deposition roll 15a, the second film deposition roll 16a, the third film deposition roll 15b and the fourth film deposition roll 16b can be properly selected so as to achieve the desired functions as an electrode.

Further, temperatures of the first film deposition roll 15a, the second film deposition roll 16a, the third film deposition roll 15b and the fourth film deposition roll 16b may be independently adjusted. The temperatures of the first film deposition roll 15a, the second film deposition roll 16a, the third film deposition roll 15b and the fourth film deposition roll 16b are not particularly limited, for example, the temperature being −30 to 100° C., but when the temperature is set at a high temperature beyond the glass transition temperature of the base 1a, there is a risk of generating deformation or the like of a base by the heat.

The magnetic field-generating devices 20a, 21a, 20b, and 21b are provided, respectively, in the first film deposition roll 15a, the second film deposition roll 16a, the third film deposition roll 15b and the fourth film deposition roll 16b. Furthermore, a highly frequent voltage for generating plasma is applied to the first film deposition roll 15a and the second film deposition roll 16a, by the power source 19a for generating plasma. A highly frequent voltage for generating plasma is applied to the third film deposition roll 15b and the fourth film deposition roll 16b, by the power source 19b for generating plasma.

Then, an electric field is formed in a deposition portion Sa between the first film deposition roll 15a and the second film deposition roll 16a, or in a deposition portion Sb between the third film deposition roll 15b and the fourth film deposition roll 16b, and there is generated a discharge plasma of a film deposition gas supplied from the gas supply pipe 18a or the gas supply pipe 18b. The applied voltage by the power source 19a for generating plasma and the applied voltage by the power source 19b for generating plasma may be the same or different. The power supply frequency of the power source 19a for generating plasma or power source 19b for generating plasma may be arbitrarily set, and according to the apparatus of the configuration, the power supply frequency is, for example, 60 to 100 kHz, and an electric power to be applied is, for example, 1 to 10 kW per 1 m effective deposition width.

The winding roll 17 has a rotation axis approximately parallel to that of the feeding roll 10, and accommodates the base 1c in the form of wound roll. The winding roll 17 can wind up the base 1c by rotating in the counter-clockwise rotation (see the arrow in FIG. 3) by a driving motor not shown. In a case of forming the first gas barrier layer 22a by using the film deposition apparatus 101, the formation (deposition) step of the first gas barrier layer 22a can be repeated several times by conveying the base 1a in the forward direction and in the reverse direction and by reciprocating the base 1a between the deposition portion Sa and the deposition portion Sb.

The base 1a fed from the feeding roll 10 is wound around the conveying rolls 11, 12a, 12b, 13a, 13b, and 14 and the first film deposition roll 15a, the second film deposition roll 16a, the third film deposition roll 15b and the fourth film deposition roll 16b, between the feeding roll 10 and the winding roll 17, and thus is conveyed by the rotation of these respective rolls while an appropriate tension is kept. Note that the conveying directions of the bases 1a, 1b, 1c, 1d, and 1e are shown by the arrows. The conveying speed (line speed) (for example, the conveying speed at the point C or the point F in FIG. 3) of the bases 1a, 1b, 1c, 1d, and 1e is appropriately adjusted depending on the kind of raw material gas, a pressure in the vacuum chamber 30, and the like. The conveying speed is adjusted by controlling the rotation speed of the driving motors of the feeding roll 10 and the winding roll 17, in the control portion 41. When the conveying speed is made slow, the thickness of the region to be formed becomes thick.

Furthermore, in a case where the film deposition apparatus 101 is used, the film-deposition step of the gas barrier film can be executed by setting the conveying direction of the bases 1a, 1b, 1c, 1d, and 1e in the opposite direction (hereinafter, referred to as reverse direction) of the direction shown by the arrow in FIG. 3 (hereinafter, referred to as forward direction). Specifically, the control portion 41 performs control so that, in the state that the base 1c is wound up by the winding roll 17, the driving motors of the feeding roll 10 and the winding roll 17 rotate in the reverse direction of the above-described case. When such control is performed, the base 1c fed from the winding roll 17 is wound around the conveying rolls 11, 12a, 12b, 13a, 13b, and 14 and the first film deposition roll 15a, the second film deposition roll 16a, the third film deposition roll 15b and the fourth film deposition roll 16b, between the feeding roll 10 and the winding roll 17, and thus is conveyed in the reverse direction by the rotation of these respective rolls while an appropriate tension is kept.

The gas supply pipes 18a and 18b supply the film deposition gas such as a raw material gas for the plasma CVD to the vacuum chamber 30. The gas supply pipe 18a has a tube-like shape extending in the same direction as the rotation axes of the first film deposition roll 15a and the second film deposition roll 16a above the deposition portion Sa, and supplies the film deposition gas to the deposition portion Sa from opening portions provided at a plurality of portions. The gas supply pipe 18b also has a tube-like shape extending in the same direction as the rotation axes of the third film deposition roll 15b and the fourth film deposition roll 16b above the deposition portion Sb, and supplies the film deposition gas to the deposition portion Sb from opening portions provided at a plurality of portions. The film deposition gas supplied from the gas supply pipe 18a and the film deposition gas supplied from the gas supply pipe 18b may be the same or may be different. Further, the pressure of the supplying gas that is supplied from these gas supply pipes is also may be the same or different.

A silicon compound may be used as the raw material gas. Examples of the silicon compounds include hexamethyldisiloxane (HMDSO), 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, dimethyldisilazane, trimethyldisilazane, tetramethyldisilazane, pentamethyldisilazane, hexamethyldisilazane, and the like. Other than these compounds, there can also be used compounds described in the paragraph [0075] of the Japanese Patent Laid-Open No. 2008-056967. Among these silicon compounds, from the viewpoints of ease of handling of the compound and the high gas barrier properties of the gas barrier film obtained, HMDSO is preferably used in the formation of the first gas barrier layer 22a. Note that these silicon compounds may be used in combination of two or more kinds. Moreover, the raw material gas may contain a mono-silane other than the silicon compounds.

A reactive gas may be used other than the raw material gas, as the film deposition gas. There are selected, as the reactive gas, gases that produce silicon compounds such as oxides and nitrides by reaction with the material gas. The reactive gas for the formation of the oxides as the thin film, which can be used, includes, for example, oxygen gas and ozone gas. Note that these reaction gases maybe used in combination of two or more kinds.

Furthermore, a carrier gas may be used as the film deposition gas for supplying the material gas to the vacuum chamber 30. Moreover, a discharge gas may be used as the film deposition gas, for generating the plasma. A rare gas such as argon, and hydrogen and nitrogen are used, for example, as the carrier gas and the discharge gas.

The magnetic field-generating devices 20a and 21a are members that form the magnetic field in the deposition portion Sa between the first film deposition roll 15a and the second film deposition roll 16a, and the magnetic field-generating devices 20b and 21b are also members that form the magnetic field in the deposition portion Sb between the third film deposition roll 15b and the fourth film deposition roll 16b. The magnetic field-generating devices 20a, 20b, 21a, and 21b do not follow the rotations of the first film deposition roll 15a and the second film deposition roll 16a, or the third film deposition roll 15b and the fourth film deposition roll 16b, and are stored at given positions.

The vacuum chamber 30 maintains, in a sealed and a reduced pressure state, the feeding roll 10, the conveying rolls 11, 12a, 12b, 13a, 13b, and 14, the first film deposition roll 15a, the second film deposition roll 16a, the third film deposition roll 15b, the fourth film deposition roll 16b, and the winding roll 17. The pressure (degree of vacuum) in the vacuum chamber 30 can be suitably adjusted depending on the kind of the raw material gas, and the like. The pressure of the deposition portion S or Sb is preferably 0.1 to 50 Pa.

The vacuum pumps 40a and 40b are connected to the control portion 41 so as to be communicable, and suitably adjust the pressure in the vacuum chamber 30 according to the instruction from the control portion 41. The control portion 41 controls each constituent element of the film deposition apparatus 101. The control portion 41 is connected to the driving motors of the feeding roll 10 and the winding roll 17, and adjusts the conveying speed of the base 1a by controlling the rotation speed of the driving motors. In addition, the conveying direction of the base 1a may be changed by controlling the rotation direction of the driving motors. Moreover, the control portion 41 is connected to supplying system of the film deposition gas not shown so as to be communicable, and controls the supplying amount of each component gas of the film deposition gas. Furthermore, the control portion 41 is connected to the power sources 19a and 19b for generating plasma so as to be communicable, and controls the output voltage and the output frequency of the power sources 19a and 19b for generating plasma. Furthermore, the control portion 41 is connected to the vacuum pumps 40a and 40b in the manner that communication is available, and controls the vacuum pumps 40a and 40b so as to maintain a predetermined reduced pressure atmosphere in the vacuum chamber 30.

The control portion 41 is provided with CPU (Central Processing Unit), HDD (Hard Disk Drive), RAM (Random Access Memory), and ROM (Read Only Memory). The HDD stores a software program describing the procedures for achieving the production method of the gas barrier film by controlling each constituent element of the film deposition apparatus 101. In addition, when the power source of the film deposition apparatus 101 is turned on, the above software program is loaded in the above RAM to be executed stepwise by the CPU. Moreover, in the ROM, there are stored various date and parameters which are used at the time when the CPU executes the software program.

### [Second Gas Barrier Layer]

The second gas barrier layer 22b is formed by application of an energy to the coating film obtained by applying and drying a coating liquid which contains a polysilazane. The second gas barrier layer 22b may be a single layer or may have a lamination structure of two or more layers. In a case where the second gas barrier layer 22b has a lamination structure of two or more layers, each second gas barrier layer 22b may have the same composition, or may have a different composition.

The thickness of the second gas barrier layer 22b (when having a lamination structure of two or more layers, total thickness) is preferably 10 to 1, 000 nm, more preferably 50 to 600 nm. When the thickness is within the range, a balance between gas barrier property and durability becomes satisfactory, which is preferable. The thickness of the second gas barrier layer 22b can be measured by TEM observation.

In the second gas barrier layer 22b, a gas barrier property is exhibited by the application of energy. Since, in the second gas barrier layer 22b, there is no contamination by foreign substances such as particles at the time of film deposition differently from a case of being formed by a vapor phase film deposition method, the obtained gas barrier layer has extremely few defects.

Furthermore, the second gas barrier layer 22b has the region (b) satisfying the composition range represented by SiO_{w}Nₓ (wherein 0.2<w≦0.55 and 0.66<x≦0.75), at a thickness of 50 to 1, 000 nm in the layer. In the second gas barrier layer 22b, the region (b) is a region having the gas barrier property and also a function as so-called a desiccant that catches water vapor by reacting with gradually intruding water vapor.

The thickness of the region (b) of the second gas barrier layer 22b is 50 to 1,000 nm. When the thickness of the region (b) is less than 50 nm, there is a risk that, since the total amount of compounds that react with water vapor becomes small as the desiccant, the amount of water vapor that can be caught is restricted, the desiccant function will be lost within the expiration date required as the device, and the gas barrier property is lowered. On the other hand, when the thickness is more than 1,000 nm, for example, in a case where the region (b) is formed by modification through energy application, there is a risk that the gas barrier property is lowered due to insufficient modification, and at the same time, the cost is increased. Furthermore, there is a concern about the generation of cracks in the second gas barrier layer 22b, and productivity is also lowered.

The thickness of the region (b) is preferably 100 to 300 nm. When the thickness is within the range, the effect of being capable of maintaining a good gas barrier property, and the effect of being capable of reducing the cost are further enhanced, during the expiration date required as the device.

The region (b) is formed by application of energy to the coating film obtained by applying and drying a coating liquid containing a polysilazane. When the region (b) exists in the second gas barrier layer 22b, the region (b) maybe in the form of existing as a single continuous region or in the form of existing as two or more regions. When there are two or more regions, the sum of the thicknesses of all regions (total thickness) may be within the above range.

The composition ratios of the silicon, oxygen and nitrogen in the region (b) and the thickness of the region (b) maybe adjusted by an arbitrary manner. For example, there may be adjusted the thickness of the coating liquid containing a polysilazane, the degree of drying after coating, the amount of energy to be applied (for example, in a case of applying energy by performing irradiation with a vacuum ultraviolet ray, illuminance, plasma density, irradiation time, and the like), the atmosphere at the time of energy application (particularly oxygen concentration), and the like. In a case of the film coating method, when the amount of energy to be applied is lowered, it is possible to lower the amount of oxygen in the composition ratio of the region. In addition, when the coating film of the coating liquid containing a polyslazane is made thick, a person skilled in the art would be able to adjust the thickness of the coating film in accordance with the desired thickness of the region since the region (b) becomes thick. Furthermore, the second gas barrier layer 22b provided with the region (b) having the above composition and the thickness may be formed by carrying out, for example, the film formation and the energy application several times alternately.

The second gas barrier layer 22b including the region (b) is formed by application of energy to the coating film obtained by applying and drying a coating liquid containing a polysilazane. Note that, in the method in which energy is applied to a coating film obtained by applying and drying a coating liquid containing a polysilazane which is one of the methods for forming the first gas barrier layer 22a, the formation conditions (kind of the polysilazane to be used, solvent used for the coating liquid, concentration of the coating liquid, kind of catalyst, application conditions of energy, and the like) are the same as described above. However, from the above reason, the region (b) is not formed in the first gas barrier layer 22a that is formed directly on the resin base 1, and even when the first gas barrier layer 22a and the second gas barrier layer 22b are formed in the same conditions, the first gas barrier layer 22a and the second gas barrier layer 22b become layers apparently different from each other.

Polysilazane is a polymer having a silicon-nitrogen bond, and is a ceramic precursor inorganic polymer such as SiO₂ and Si₃N₄, and SiOₓN_{y} that is an intermediate solid solution of the both, having bonds such as Si—N, Si—H, N—H, and the like. Specifically, the polysilazane preferably has a structure below.

[Chemical formula 1]

—[Si(R₁)(R₂)—N(R₃)]ₙ— General formula (I)

In the above General formula (I), R₁, R₂, and R₃ are, independently, a hydrogen atom; or a substituted or unsubstituted alkyl group, aryl group, vinyl group, or (trialkoxysilyl)alkyl group. In this case, R₁, R₂ and R₃ may be the same as or different from each other, respectively. Here, examples of the alkyl groups include a linear chain, branched chain, or cyclic alkyl group having 1 to 8 carbon atoms. More specific examples thereof may include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an n-heptyl group, an n-octyl group, a 2-ethylhexyl group, a cyclopropyl group, a cyclopentyl group, a cyclohexyl group, and the like. In addition, examples of the aryl group may include an aryl group having 6 to 30 carbon atoms. More specific examples thereof include a non-condensed hydrocarbon group such as a phenyl group, a biphenyl group, and a terphenyl group; and a condensed polycyclic hydrocarbons group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, and a naphthacenyl group. Examples of the (trialkoxysilyl)alkyl group include an alkyl group having 1 to 8 carbon atoms that has a silyl group substituted with an alkoxy group having 1 to 8 carbon atoms. More specific examples thereof include a 3-(triethoxysilyl)propyl group, a 3-(trimethoxysilyl)propyl group, and the like. A substituent that is present in the R₁ to R₃, in some cases, is not particularly limited, but examples thereof include an alkyl group, a halogen atom, a hydroxyl group (—OH), a mercapto group (—SH), a cyano group (—CN), a sulfo group (—SO₃H), a carboxyl group (—COOH), a nitro group (—NO₂), and the like. Note that a substituent that is present in some cases is not the same as R₁ to R₃ to be substituted. For example, when R₁ to R₃ are an alkyl group, further substitution with an alkyl group is not performed. Among them, preferably, R₁, R₂, and R₃ are each a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group or a 3-(trimethoxysilylpropyl) group.

In addition, in the above General formula (I), n is an integer, and is preferably determined such that the polysilazane having the structure represented by General formula (I) has a number-average molecular weight of 150 to 150,000 g/mole.

In the compound having the structure represented by General formula (I), one of preferred embodiments is a perhydropolysilazane, in which all of R₁, R₂, and R₃ are hydrogen atoms.

Alternatively, the polysilazane has a structure represented by the following General formula (II).

[Chemical formula 2]

—[Si(R_{1′})(R_{2′})—N(R_{3′})]_{n′}—[Si(R_{4′})(R_{5′})—N(R_{6′})]ₚ— General formula (II)

In the above General formula (II), R_{1′}, R_{2′}, R_{3′}, R_{4′}, R_{5′}, and R_{6′} are respectively independently a hydrogen atom; and a substituted or unsubstituted alkyl group, aryl group, vinyl group, or (trialkoxysilyl)alkyl group. At this time, R_{1′}, R_{2′}, R_{3′}, R_{4′}, R_{5′}, and R_{6′}, may be the same as or different from each other, respectively. The description on the substituted or unsubstituted alkyl group, aryl group, vinyl group, or (trialkoxysilyl)alkyl group is the same as the definition in General formula (I), and thus, is omitted.

Moreover, in the above General formula (II), the n′ and p are an integer, and preferably determined such that the polysilazane having the structure represented by General formula (II) has a number-average molecular weight of 150 to 150,000 g/mole. Note that n′ and p may be the same as or different from each other.

Among the polysilazanes of the General formula (II), a compound is preferable in which R_{1′}, R_{3′}, and R_{6′}, are each a hydrogen atom, R_{2′}, R_{4′}, and R_{5′}, are each a methyl group, respectively; a compound in which R_{1′}, R_{3′}, and R_{6′} are each a hydrogen atom, R_{2′} and R_{4′} are each a methyl group, and R_{5′} is a compound that represents a vinyl group; and a compound in which R_{1′}, R_{3′}, R_{4′}, and R_{6′} are each a hydrogen atom, and R_{2′} and R_{5′} are each a methyl group.

Alternatively, the polysilazane has a structure represented by the following General formula (III).

[Chemical formula 3]

—[Si(R_{1″})(R_{2″})—N(R_{3″})]_{n″}—[Si(R_{4″})(R_{5″})—N(R_{6″})]_{p″}—[Si(R_{7″})(R_{8″})—N(R_{9″})]_{q}— General formula (III)

In the above General formula (III), R_{1″}, R_{2″}, R_{3″}, R_{4″}, R_{5″}, R_{6″}, R_{7″}, R_{8″}, and R_{9″} are respectively independently a hydrogen atom; or a substituted or unsubstituted alkyl group, aryl group, vinyl group, or (trialkoxysilyl) alkyl group. At this time, R_{1″}, R_{2″}, R_{3″}, R_{4″}, R_{5″}, R_{6″}, R_{7″}, R_{8″}, and R_{9″} may be the same as or different from each other, respectively. The description about the above substituted or unsubstituted alkyl group, aryl group, vinyl group, or (trialkoxysilyl)alkyl group is the same as the definition of the above General formula (I), and thus, is omitted.

In addition, in the above General formula (III), n″, p″ and q are each an integer, and are preferably determined such that the polysilazane having the structure represented by General formula (III) has a number-average molecular weight of 150 to 150,000 g/mole. Note that n″, p″ and q may be the same as or different from each other.

Among the polysilazanes of General formula (III), a compound is preferable in which R_{1″}, R_{3″}, and R_{6″} are each a hydrogen atom, R_{2″}, R_{4″}, R_{5″}, and R_{8″} are each a methyl group, and R_{9″} is a (triethoxysilyl)propyl group, and R_{7″} is an alkyl group or a hydrogen atom.

On the other hand, organopolysilazane in which a part of the hydrogen portion to be bonded to Si thereof is substituted by an alkyl group or the like has the advantage that the generation of crack is suppressed even when (an average) film thickness is made larger, because adhesiveness to the first gas barrier layer 22a being a base is improved by having an alkyl group such as a methyl group and toughness can be given to a ceramic film made of hard and fragile polysilazane. Therefore, these perhydropolysilazane and organopolysilazane may be suitably selected depending on use applications, or can also be used in mixture.

The perhydropolysilazane is presumed to have a structure with a linear structure and a ring structure centering on the 6- and 8-membered rings. The molecular weight thereof is approximately 600 to 2000 (in terms of polystyrene) in number-average molecular weight (Mn), and the perhydropolysilazane is a liquid or solid material and the state differs depending on its molecular weight.

The polysilazane is commercially available in the form of a solution dissolved in an organic solvent, and a commercially available product can be used as is, as a coating liquid for forming the second gas barrier layer 22b. Examples of the commercially available polysilazane solutions include NN120-10, NN120-20, NAX120-20, NN110, NN310, NN320, NL110A, NL120A, NL120-20, NL150A, NP110, NP140, SP140, and the like, manufactured by AZ Electronic Materials Co., Ltd.

Other examples of polysilazanes changing into ceramic at low temperatures include siliconalkoxide-added polysilazane obtained by causing polysilazane described above to react with siliconalkoxide (Japanese Patent Laid-Open No. 05-238827), glycidol-added polysilazane obtained by causing the polysilazane to react with glycidol (for example, Japanese Patent Laid-Open No. 06-122852), alcohol-added polysilazane obtained by causing the polysilazane to react with alcohol (Japanese Patent Laid-Open No. 06-240208), metal carboxylate-added polysilazane obtained by causing the polysilazane to react with metal carboxylate (Japanese Patent Laid-Open No. 06-299118), acetylacetonate complex-added polysilazane obtained by causing the polysilazane to react with acetylacetonate complex containing a metal (Japanese Patent Laid-Open No. 06-306329), metal-fine-particle-added polysilazane obtained by adding metal fine particles (Japanese Patent Laid-Open No. 07-196986), and the like.

When the polysilazane is used, a content of the polysilazane in the second gas barrier layer 22b before the application of the energy is 100% by mass when the whole mass of the second gas barrier layer 22b is assumed to be 100% by mass. Furthermore, when the second gas barrier layer 22b contains a substance other than the polysilazane, the content of the polysilazane in the layer is preferably 10% by mass or more and 99% by mass or less, more preferably 40% by mass or more and 95% by mass or less, particularly preferably 70% by mass or more and 95% by mass or less.

### (Coating Liquid for Forming Second Gas Barrier Layer)

The solvent for preparing the coating liquid for forming the second gas barrier layer 22b is not particularly limited as long as the polysilazane can be dissolved, and preferable is an organic solvent which does not contain water and a reactive group (for example, hydroxyl group, amine group, or the like) readily reacting with the polysilazane and which is inert to the polysilazane, and particularly preferable is a non-proton organic solvent. Examples of the solvents include: non-proton solvents; for example, hydrocarbon solvents including an aliphatic hydrocarbon, an alicyclic hydrocarbon and an aromatic hydrocarbon such as pentane, hexane, cyclohexane, toluene, xylene, Solvesso, turpentine, and the like; halogenated hydrocarbon solvents such as methylene chloride and trichloroethane; esters such as ethyl acetate and butyl acetate; ketones such as acetone and methyl ethyl ketone; ethers including an aliphatic ether and an alicyclic ether such as dibutyl ether, dioxane, and tetrahydrofuran; for example, tetrahydrofuran, dibutyl ether, mono- and poly-alkulene glycol dialkyl ether (diglymes), and the like. The above solvents may be selected depending on the solubility of the polysilazane and evaporation rate of the solvent, and may also be used alone or in the form of mixture of two or more kinds.

The concentration of the polysilazane in the coating liquid for forming the second gas barrier layer 22b is not particularly limited, is different depending on the film thickness of the layer and the pot life of the coating liquid, and is preferably 1 to 80% by mass, more preferably 5 to 50% by mass, further preferably 10 to 40% by mass.

The coating liquid for forming the second gas barrier layer 22b may contain preferably a catalyst in order to accelerate the modification. The catalyst is preferably a basic catalyst, and examples include an amine catalyst such as N,N-diethylethanolamine, N,N-dimethylethanolamine, triethanolamine, triethylamine, 3-morpholinopropylamine, N,N,N′,N′-tetramethyl-1,3-diaminopropane, or N,N,N′,N′-tetramethyl-1,6-diaminohexane; a metal catalyst such as a Pt compound such as Pt acetylacetonato, a Pd compound such as Pd propionate, a Rh compound such as Rh acetylacetonato; a N-heterocyclic compound. Among them, the amine catalyst is preferably used. In this case, the concentration of the catalyst to be added is preferably within the range of 0.1 to 10% by mass, more preferably within the range of 0.5 to 7% by mass on the basis of the silicon compound. When the amount of the catalyst to be added is within the above range, it is possible to avoid the formation of excess silanol groups due to a rapid reaction, a decrease in the film density, and an increase in film defects.

The additives that are exemplified below can be used for the coating liquid for forming the second gas barrier layer 22b, as necessary. Examples thereof include cellulose ethers, cellulose esters; for example, natural resins such as ethyl cellulose, nitrocellulose, cellulose acetate, and cellulose acetbutyrate; for example, synthetic resins such as rubber and rosin resins; for example, polymeric resins and condensation resins; for example, aminoplast, particularly urea resins, melamine formaldehyde resins, alkyd resins, acrylic resins, polyester or denatured polyester, epoxide, polyisocyanate, or blocked polyisocyanate, polysiloxane, and the like.

### (Method for Applying the Coating Liquid for Forming Second Gas Barrier Layer)

A appropriate wet coating method that is conventionally known can be adopted as a method for applying a coating liquid for forming second gas barrier layer 22b. Specific examples include a spin coating method, a roll coating method, a flow coating method, an ink-jet method, a spray coating method, a printing method, a dip coating method, a film casting method, a bar coating method, a die coating method, a gravure printing method, and the like.

The coating thickness can be appropriately determined depending on a preferred thickness and objects. One example is that a thickness of the coating liquid (coating film) after drying (a thickness for each coating when the coating film formation is carried out multiple times) is preferably 40 nm or more and 1,000 nm or less, more preferably 100 nm or more and 300 nm or less.

After the coating liquid is applied the coating film is preferably dried. The organic solvent contained in the coating film can be removed by drying the coating film. At this time, all the organic solvent contained in the coating film may be removed, or may partly remain. In a case where the organic solvent partly remains, a suitable second gas barrier layer 22b can be obtained. Note that the remaining solvent will be removed later.

The temperature of drying the coating film is varied due to the base to be applied, and is preferably 50 to 200° C. For example, when a polyethylene terephthalate base having a glass transition temperature (Tg) of 70° C. is used as abase, the drying temperature is set to 150° C. or less considering the deformation of the base by heat, and the like. The above temperature can be set by using a hot plate, an oven, a furnace, or the like. The drying time is preferably set to a short period of time, and for example, when the drying temperature is 150° C., the drying time is set to within 30 minutes. Moreover, the drying atmosphere maybe any condition such as under the air atmosphere, under nitrogen atmosphere, under argon atmosphere, under vacuum atmosphere, and under an atmosphere where an oxygen concentration is regulated.

The coating film obtained by applying the coating liquid for forming the second gas barrier layer 22b may include a step where water is removed before the application of energy, or during the application of energy. As a method for removing water, it is preferable to use a type of the dehumidification by maintaining the environment of low humidity. The humidity in the environment of low humidity changes according to a temperature, and thus, the preferred type of the relation between the temperature and humidity is exhibited by the determination of a dew-point temperature. The preferred dew-point temperature is 4° C. (Temperature of 25° C./Humidity of 25%) or less, and more preferably −5° C. (Temperature of 25° C./Humidity of 10%) or less, and it is preferable to set properly the time to be maintained by the film thickness of the second gas barrier layer 22b. For the condition that the film thickness of the second gas barrier layer 22b is 1.0 μm or less, it is preferable that the dew-point temperature be −5° C. or less and the time to be maintained be one minute or longer. Note that the lower limit of the dew-point temperature is not particularly limited, and is usually −50° C. or more, preferably −40° C. or more. The embodiment where water is removed before the modification treatment or during the modification treatment is preferable, because the dehydration reaction of the second gas barrier layer 22b which is converted to silanol can be accelerated.

### (Application of Energy)

Subsequently, the energy is applied to the thus formed coating film to convert the polysilazane to silicon oxide, silicone oxide nitride, or the like, thereby the second gas barrier layer 22b is modified to an inorganic thin film which exhibits gas barrier properties.

The conversion reaction of the polysilazane to the silicon oxide, the silicon oxide nitride, or the like, may be carried out by selecting a known method optionally. Specifically, examples of the modification treatment include a plasma treatment, an ultraviolet ray irradiation n treatment and a heat treatment. However, in case of the heat treatment, since a high temperature of 450° C. or more is required in order to form a silicon oxide film or a silicon oxide nitride layer by the substitution reaction of the silicon compound, it is difficult to apply the heat treatment to a flexible substrate such as plastics. Therefore, it is preferable that the heat treatment is carried out in combination of the other modification treatments.

Accordingly, as the modification treatment, from the viewpoint of using the plastic substrate, it is preferable to employ the conversion reaction through the plasma treatment and the ultraviolet ray irradiation treatment which can convert at a lower temperature. Hereinafter, the preferred plasma treatment and the ultraviolet ray irradiation treatment will be explained.

### (Plasma Treatment)

A known method can be used for a plasma treatment as the modification treatment, and an atmospheric pressure plasma treatment or the like is preferable. According to the atmospheric pressure plasma CVD method in which a plasma CVD treatment is conducted under a pressure near the atmospheric pressure, in comparison with a plasma CVD method conducted under vacuum, the productivity is high because reduction of pressure is not necessary, a film forming speed is fast because the plasma density is high, and further, in comparison with the conditions of a usual CVD method, an extremely homogeneous film can be obtained under a high pressure condition of the atmospheric pressure where a mean free pass of the gas is very short.

In a case of the atmospheric pressure plasma treatment, nitrogen gas and/or atoms in Group XVIII in the long-period-type periodic table, specifically, helium, neon, argon, krypton, xenon, radon or the like is used as a discharge gas. Among them, nitrogen, helium and argon is used preferably, and in particular, nitrogen is low in cost and preferable.

### (Ultraviolet Ray Irradiation Treatment)

A treatment by ultraviolet ray irradiation is also preferable as one of the modification treatments. Ozone and active oxygen atoms generated by ultraviolet ray (the same meaning as ultraviolet light) has a high oxidation capability, and a silicon oxide film or a silicon oxide nitride film having high denseness and insulation performance at low temperatures can be formed.

The substrate is heated by the ultraviolet ray irradiation, and O₂ and H₂O contributing to ceramic formation (silica conversion), an ultraviolet absorber and the polysilazane itself are excited and activated, and thus the excitation of the polysilazane accelerates the ceramic formation of the polysilazane, and the obtained ceramic film becomes dense. The ultraviolet ray irradiation may be effectively carried out at any time after formation of the coated film.

In the ultraviolet ray irradiation treatment, any of the ultraviolet ray generation apparatuses that are commonly used can also be used. Note that “ultraviolet ray” generally means an electromagnetic wave having a wavelength of 10 to 400 nm, and in the case of the ultraviolet ray irradiation treatment except for a vacuum ultraviolet ray (10 to 200 nm) treatment to be described later, preferably ultraviolet rays of 210 to 375 nm are used.

In the ultraviolet ray irradiation, an irradiation intensity and irradiation time are set within a range not of damaging the base holding the second gas barrier layer 22b to be irradiated. When taking, as an example, the case where a plastic film is used as the substrate, it is possible to set the distance between the substrate-lamp so that the intensity on the substrate surface becomes 20 to 300 mW/cm², preferably 50 to 200 mW/cm² for 0.1 sec to 10 min by, for example, using a lamp of 2 kW (80 W/cm×25 cm), and to perform the irradiation for 0.1 sec to 10 min.

Generally, when the base temperature at the time of the ultraviolet ray irradiation treatment becomes 150° C. or more, damage of the base such as the deformation or strength degradation of the base is carried out in the case of a plastic film or the like. However, in the case of a film having high heat resistance such as polyimide and a substrate of metal or the like, a treatment at higher temperatures is possible. Accordingly, there is no general upper limit on the base temperature at the time of the ultraviolet ray irradiation, and a person skilled in the art can suitably set the base temperature depending on kinds of the substrates. Furthermore, an ultraviolet ray irradiation atmosphere is not particularly limited and the ultraviolet ray irradiation may be performed in the air.

Examples of generation methods of the ultraviolet ray include metal halide lamp, high-pressure mercury vapor lamp, low-pressure mercury vapor lamp, xenon arc lamp, carbon arc lamp, excimer lamp (single wavelength of 172 nm, 222 nm, 308 nm, for example, manufactured by USHIO INC., M.D.Com. Inc., etc.), an UV light laser, and the like, but the generation methods are not particularly limited. Furthermore, in irradiating a second gas barrier layer 22b with the generated ultraviolet ray, the second gas barrier layer 22b is desirably irradiated with the ultraviolet ray from a generation source, reflected from a reflection plate, also in order to achieve efficiency enhancement and uniform irradiation.

The ultraviolet ray irradiation is applicable to both a batch treatment and a continuous treatment, and an appropriate selection is possible depending on shape of a base to be used. For example, in the case of a batch treatment, a laminated body having the second gas barrier layer 22b on the surface thereof can be treated with a burning furnace provided with the above-described ultraviolet ray generation source. The ultraviolet ray burning furnace itself is generally known, and for example, an ultraviolet ray burning furnace manufactured by EYE GRAPHICS CO., LTD. can be used. Furthermore, when the laminated body having the second gas barrier layer 22b on the surface is in a shape of long film, the formation into ceramic can be performed by a drying zone provided with such ultraviolet ray generation source as described above continuously irradiating the long film with ultraviolet rays while conveying the long film. A time period required for the ultraviolet ray irradiation is generally 0.1 sec to 10 min, preferably 0.5 sec to 3 min, although the time period depends on a base to be used, and the composition and concentration of the second gas barrier layer 22b.

### (Vacuum Ultraviolet Ray Irradiation Treatment: Excimer Irradiation Treatment)

The most preferable modification treatment method is a treatment by using a vacuum ultraviolet ray irradiation (excimer irradiation treatment). The treatment by vacuum ultraviolet ray irradiation is a method in which, through the use of an optical energy of 100 to 200 nm lager than the inter-atomic bonding strength in the polysilazane compound, preferably, through the use of an energy of light having a wavelength of 100 to 180 nm, a silicon oxide film is formed at a relatively low temperature (about 200° C. or less) by advancing an oxidation reaction using active oxygen or ozone while directly cutting the bonding of atoms by an action only of photons referred to as a photon process. Note that, in carrying out the excimer irradiation treatment, it is preferable to use the heat treatment together as mentioned above.

The radiation source may be one that generates light having a wavelength of 100 to 180 nm, and preferably an excimer radiator having a maximum radiation at about 172 nm (for example, Xe excimer lamp), a low-pressure mercury-vapor lamp having a bright line at about 185 nm, and a medium pressure and high-pressure mercury-vapor lamp having a wavelength component of 230 nm or less, and an excimer lamp having a maximum radiation at about 222 nm.

Among them, the Xe excimer lamp radiates an ultraviolet ray having a single short wavelength of 172 nm, and thus the Xe excimer lamp is excellent in light emission efficiency. Since the light has a large absorption coefficient of oxygen, radical oxygen atomic species and ozone can be generated at a high concentration by the use of a trace amount of oxygen.

Furthermore, it is known that light energy having a short wavelength of 172 nm has a high capacity of dissociating the bonding of an organic substance. Modification of the polysilazane-containing coating film can be realized in a short period of time by these active oxygen and ozone and the high energy of ultraviolet ray radiation.

Since the excimer lamp has a high generation efficiency of light, the excimer lamp can be turned on by the supply of a low electric power. Furthermore, since the excimer lamp does not emit light having a long wavelength which is a factor of the temperature increase, and performs irradiation with energy within the ultraviolet ray region, namely, at short wavelengths, there is a feature in which the increase in the surface temperature of the object to be radiated can be suppressed. Accordingly, the excimer lamp is suitable for a flexible film material such as PET which is considered to be easily affected by heat.

A reaction during irradiation with the ultraviolet ray requires oxygen, but since a vacuum ultraviolet ray is easily prone to decrease efficiency in an ultraviolet ray irradiation process due to absorption by oxygen, it is preferable to perform the irradiation with a vacuum ultraviolet ray in a state where an oxygen concentration and a water vapor concentration are as low as possible. Namely, the oxygen concentration during the irradiation with a vacuum ultraviolet ray is preferably 10 to 20,000 ppm by volume (0.001 to 2% by volume), more preferably 50 to 10,000 volume ppm (0.005 to 1% by volume). In addition, the water vapor concentration between the conversion processes is preferably within the range of 1,000 to 4,000 volume ppm.

A dry inert gas is preferred as a gas filling an irradiation atmosphere used during the irradiation with a vacuum ultraviolet ray, and a dry nitrogen gas is particularly preferred from the viewpoint of a cost. The oxygen concentration can be adjusted by measuring the flow rates of an oxygen gas and an inert gas introduced into an irradiation house and by changing a flow ratio.

In the vacuum ultraviolet ray irradiation process, the illuminance of the vacuum ultraviolet rays on the coating film surface of the polysilazane coating film is preferably 1 mW/cm² to 10 mW/cm², more preferably 30 mW/cm² to 200 mW/cm², further preferably 50 mW/cm² to 160 mW/cm². When 1 mW/cm² or more, the modification efficiency is enhanced, and when 10 mW/cm² or less, it is possible to lower the ablation that can be generated in the coating film and the damage to the base.

The irradiation energy amount (irradiation amount) of the vacuum ultraviolet ray on the coating film surface is preferably 100 mJ/cm² to 50 J/cm², more preferably 200 mJ/cm² to 20 J/cm², further preferably 500 mJ/cm² to 10 J/cm². When 100 mJ/cm² or more, the modification is sufficient, and when 50 J/cm² or less, it is possible to suppress the generation of cracks due to excessive modification and the thermal deformation of the base.

In addition, the vacuum ultraviolet ray to be used may be generated from a plasma formed of a gas which contains at least one of CO, CO₂ and CH₄. Furthermore, although the carbon-containing gas may be used alone as the gas which contains at least one of CO, CO₂ and CH₄ (hereinafter, referred to also as carbon-containing gas), it is preferable that a small amount of the carbon-containing gas may be added to a gas that contains a rare gas or H₂ as a main gas. There is included a volume bonding plasma, or the like, as a method for generating plasma.

Note that the distribution of composition in the thickness direction and the thickness of the region (b) can be determined by measurement using a method in which the following XPS (photoelectron spectroscopy) analysis is used.

The etching rate of the region (b) is varied depending on the composition. Accordingly, once an etching rate is calculated on the basis of a SiO₂ conversion, an etching rate is calculated by determine the interface of each layer in the region which is formed by laminating on the basis of the sectional TEM image of a sample to be measured. While comparing the obtained thickness per one layer with a distribution of the composition in the thickness direction obtained from the XPS analysis, each layer is identified in the distribution of the composition in the thickness direction, a certain coefficient is applied evenly to the thickness of each region obtained from the XPS analysis so that the thickness of each region obtained from the corresponding XPS analysis coincides with the thickness of each region obtained from the sectional TEM image. According to the XPS analysis, compensation in the thickness direction is done as described above.

The XPS analysis is carried out under the following conditions, and even if the machine and measuring conditions are changed, when the resolution in the thickness direction is that an etching depth per one measuring point (corresponding to the following Sputtering ion and depth profile condition) is 1 to 15 nm, preferably 1 to 10 nm, it is possible to apply without any trouble.

### (XPS Analysis Conditions)

Machine: manufactured by ULVAC-PHI, INCORPORATED

X-Ray source: Monochromatic Al-Kα

Measurement region: Si2p, C1s, N1s, O1s

Sputtering ion: Ar (2 keV)

Depth profile: The measurement is repeated after sputtering for a given period of time. The sputtering period of time is adjusted so that a thickness in terms of SiO₂ becomes about 2.8 nm in one measurement.

Quantification: Quantification is carried out by obtaining the background according to the Shirley method, and by using the relative sensibility coefficient method, from the obtained peak area. The data processing is performed by the use of MultiPak manufactured by ULVAC-PHI, INCORPORATED.

According to the above procedures, there is obtained a first data of the profile of the composition distribution in the thickness direction of the second gas barrier layer 22b.

Furthermore, each thickness of the lamination structure is obtained by photographing the cross-section of each sample through the use of the TEM. The above obtained profile of the composition distribution in the thickness direction is corrected by the use of the actual thickness data obtained from the TEM image to thereby give the composition distribution of the region in the thickness direction. The thickness of the region (b) is obtained on the basis of the distribution.

In a method for obtaining a thickness per one region from the TEM image, the cross-sectional TEM observation according the usual method may be carried out after fabricating a thin piece of the gas barrier film by the use of the following FIB processing machine. Accordingly, the thickness of each region can be calculated. Examples that can be used for the FIB processing and the TEM observation are as follows.

### (FIB Processing)

Apparatus: SMI2050 manufactured by SII

Processing ion: (Ga 30 kV)

Thickness of sample: 100 nm to 200 nm

### (TEM Observation)

Apparatus: JEM2000FX manufactured by JEOL, Ltd. (acceleration voltage: 200 kV)

### [Third Gas Barrier Layer]

The third gas barrier layer 22c contains, as a main component, an oxide of a metal having a lower redox potential than silicon. The third gas barrier layer 22c may be a single layer or a lamination structure of two or more layers. In a case where the third gas barrier layer 22c has a lamination structure of two or more layers, each third gas barrier layer 22c may have the same composition, or may have a different composition.

The thickness of the third gas barrier layer 22c (in a case of having a lamination structure of two or more layers, total thickness) is not particularly limited, and is preferably 1 to 500 nm, more preferably 5 to 200 nm. When the thickness is within the range, there is an advantage that a sufficient enhancement effect of the gas barrier property can be obtained within the deposition tact time of high productivity.

Although only the third gas barrier layer 22c containing, as a main component, an oxide of a metal that has a lower redox potential than silicon does not have a high gas barrier property that makes the dark spot of the organic EL element lower, for example, the third gas barrier layer is oxidized earlier than the region (b) of the second gas barrier layer 22b under the high temperature and high humidity circumstance. Therefore, the suppression effect of the oxidation of the surface of the second gas barrier layer 22b under the high temperature and high humidity circumstance is exhibited, and thus it is considered that the local lowering of the gas barrier property is difficult to be generated. Therefore, when the third gas barrier layer 22c is provided, the durability of the gas barrier film under the high temperature and high humidity circumstance can be enhanced.

The wording “contain, as a main component, an oxide of a metal that has a lower redox potential than silicon” in the third gas barrier layer 22c means that a content of the oxide of a metal that has a lower redox potential than silicon is 50% by mass or more relative to the whole mass of the third gas barrier layer 22c. The content is more preferably 80% by mass or more, further preferably 95% by mass or more, particularly preferably 98% by mass or more, most preferably 100% by mass (namely, the third gas barrier layer 22c is made of only the oxide of a metal that has a lower redox potential than silicon).

Examples of metals each having a lower redox potential than silicon include niobium, tantalum, zirconium, titanium, hafnium, magnesium, yttrium, aluminum, and the like. These metals maybe used alone or in combination of two or more kinds. Among them, at least one selected from the group consisting of niobium, tantalum, zirconium and titanium is preferable. Namely, the third gas barrier layer 22c preferably contains, as a main component, an oxide of at least one metal selected from the group consisting of niobium, tantalum, zirconium and titanium.

The standard redox potentials of main metals are shown in Table 1.

TABLE 1

| | Standard | |
|---|---|---|
| | redox | |
| | potential | |
| Metal | (V) | Oxide |
| Zn | −0.80 | ZnO |
| Si | −0.91 | SiO₂ |
| Nb | −1.10 | Nb₂O₅ |
| Ta | −1.12 | Ta₂O₅ |
| Zr | −1.53 | ZrO₂ |
| Ti | −1.63 | TiO₂ |
| Hf | −1.70 | HfO₂ |
| Mg | −2.30 | MgO |
| Y | −2.37 | Y₂O₃ |
| Al | −2.40 | Al₂O₃ |

From the viewpoint that the suppression effect of oxidation to the surface of the second gas barrier layer 22b is easily exhibited, the third gas barrier layer 22c preferably contains at least one of metal oxides of niobium or tantalum as a main component. In the preferred embodiment, if the third gas barrier layer 22c contains, as a main component, the oxide of a metal having a lower redox potential than silicon, other compounds may be contained. Examples of the other compounds include hafnium, magnesium, yttrium, aluminum, and the like. These other compounds may be used alone or in combination of two or more.

The method for forming the third gas barrier layer 22c is not particularly limited, and examples thereof include a physical vapor deposition (PVD) method such as sputtering method, vapor deposition method, ion plating method, a chemical vapor deposition method such as plasma CVD (plasma-enhanced chemical vapor deposition, PECVD) method, ALD (Atomic Layer Deposition). Among them, from the viewpoint that the film formation is possible without giving damage to the second gas barrier layer 22b which is provided at the lower portion, and that the productivity is high, it is preferable to form the second gas barrier layer 22b by the sputtering method.

There can be used, for the film deposition by the use of the sputtering method, a conventional method such as a DC (direct current) sputtering method, an RF (high frequency) sputtering method, a method in which these magnetron sputtering methods are combined, and a dual magnetron (DMS) sputtering method using a dual frequency region, alone or in combination of two or more kinds. In addition, it is possible to use a reactive sputtering method of utilizing a transition mode that is an intermediate mode of a metal mode and an oxide mode. A metal oxide film can be deposited at a high film deposition speed by control of a sputtering phenomenon so as to be a transition region, and thus it is preferable. In carrying out the DC sputtering and the DMS sputtering, it is possible to form a thin film of an oxide of a metal that has a lower redox potential than silicon, by using a metal that has a lower redox potential than silicon as the target and furthermore by introducing oxygen into a process gas. Moreover, in a case of performing film deposition according to the RF (high frequency) sputtering method, it is possible to use an oxide of a metal that has a lower redox potential than silicon as a target. There can be used, as the process gas, at least one process gas or the like among: an inert gas such as He, Ne, Ar, Kr or Xe; oxygen; nitrogen; carbon dioxide; and carbon monoxide. The film deposition conditions in the sputtering method are electric power to be applied, discharge current, discharge voltage, period of time, and the like, and these can be appropriately selected depending on a sputtering device, a material of the film, a film thickness, and the like. Among them, preferable is a sputtering method in which the oxide of a metal that has a lower redox potential than silicon is used as a target, because of high film deposition rate and high productivity.

[Layers having Various Functions]

The gas barrier film may include layers other than the above-described barrier layers. For example, layers having various functions such as an anchor coating layer and a smooth layer.

### (Anchor Coating Layer)

An anchor coating layer may be formed on the surface of the resin base 1 on the side where the gas barrier layer 22 is formed, in order to enhance the adherence to the gas barrier layer 22. The thickness of the anchor coating layer is not particularly limited, and is preferably approximately 0.5 to 10 μm.

There can be used, as an anchor coating agent used for the anchor coating layer, a polyester resin, an isocyanate resin, a urethane resin, an acrylate resin, an ethylene vinyl alcohol resin, a vinyl modified resin, an epoxy resin, a modified styrene resin, a modified silicone resin, an alkyl titanate, and the like, alone or in combination of two or more kinds.

A conventional known additives can be added to the anchor coating agent. In addition, the anchor coating can be performed by applying the above anchor coating agent to a support body through a known method such as a roll coating, a gravure coating, a knife coating, a dip coating or a spray coating, and then by drying and removing the solvent and diluent and the like. The amount to be applied of the anchor coating agent is preferably approximately 0.1 to 5.0 g/m² (dry state).

Furthermore, the anchor coating layer can be formed by the gas phase method such as the physical vapor deposition method or the chemical vapor deposition method. For example, as described in Japanese Patent Laid-Open No. 2008-142941, an inorganic film having silicon oxide as a main component can be formed in order to improve adherence and the like. Alternatively, it is also possible to form an anchor coating layer in order to control the composition of the inorganic thin film, by cutting off a gas generated from the base side to some extent at the time when forming, on an anchor coating layer, the inorganic thin film according to the gas phase method by forming the anchor coating layer described in Japanese Patent Laid-Open No. 2004-314626.

### (Smooth Layer)

The gas barrier film may have a smooth layer between the resin base 1 and the first gas barrier layer 22a. The smooth layer is provided in order to smooth the rough surface of the resin base 1 in which projections exist. The thickness of the smooth layer is, from the viewpoints that the heat resistance of the film is enhanced and that the balance adjustment of the optical properties of the film is facilitated, preferably within the range of 1 to 10 μm, more preferably within the range of 2 μm to 7 μm.

The smooth layer is formed basically by curing a photosensitive material, or a heat curable material.

Examples of the photosensitive materials include: a resin composition containing an acrylate compound having a radical reactive unsaturated compound; a resin compound containing an acrylate compound and a mercapto compound having a thiol group; and resin compositions obtained by dissolving multifunctional acrylate monomers such as epoxy acrylate, urethane acrylate, polyester acrylate, polyether acrylate, polyethylene glycol acrylate, or glycerol methacrylate. Specifically, there can be used a UV curable-type organic/inorganic hybrid hard coat material of OPSTAR (registered trademark) series manufactured by JSR. Furthermore, it is possible to use an arbitrary mixture of the above resin compositions, and there is no limitation as long as the photosensitive resin has a reactive monomer which has one or more photopolymerizable unsaturated bonds in one molecule.

Examples of the heat curable materials include: tutoProm series (organic polysilazane) manufactured by Clariant Ltd.; SP COAT heat-resistant clear coating material manufactured by Ceramic Coat Co., Ltd.; nanohybrid silicone manufactured by ADEKA Corporation; UNIDIC (Registered trademark) V-8000 Series and EPICLON (Registered trademark) EXA-4710 (super-high-heat-resistant epoxy resin), manufactured by DIC Corporation; various silicone resins manufactured by Shin-Etsu Chemical Co., Ltd.; inorganic-organic nanocomposite material SSG coat manufactured by Nitto Boseki Co., Ltd.; thermosetting urethane resins including acrylic polyols and isocyanate prepolymers; phenol resins; urea melamine resins; epoxy resins; unsaturated polyester resins; silicone resins; and the like. Among them, epoxy resin based materials having heat resistance are particularly preferred.

A method for forming the smooth layer is not particularly limited, and is preferably formed by a wet coating method such as a spin coating method, a spray method, a blade coating method or a dip method, or by a dry coating method such as a vapor deposition method. In formation of a smooth layer, additives such as an antioxidant, an ultraviolet absorber, and a plasticizer can be added to the above described photosensitive resins, as necessary. In addition, suitable resins and additives may also be used for enhancement of a film deposition property, prevention of generation of pin holes and the like, also in any smooth layer irrespective of a lamination position of the smooth layer.

As to the smoothness of the smooth layer, the ten-point average roughness Rz is preferably 10 nm or more and 30 nm or less in terms of a value expressed by the surface roughness defined in JIS B 0601:2001. If the roughness Rz is within the range, even in a case where the barrier layer is formed by a coating system, or in a case where a coating means is brought into contact with the surface of the smooth layer by a coating system of a wire bar, a wireless bar or the like, the smoothness is less damaged, and it is also easy to smoothen the unevenness after the coating.

### <2. Embodiment of Organic Electroluminescent Element>

Next, there will be explained the embodiment of the organic electroluminescent element (organic EL element) using the above gas barrier film. The organic EL element of the present embodiment has a configuration in which the electrodes (anode, cathode) and the light-emitting unit are provided on the above-described gas barrier film. The gas barrier film of the organic EL element is similar to the above embodiment of the gas barrier film. Therefore, in an explanation of the organic EL element, the detailed explanation of the gas barrier film is omitted.

### [Configuration of Organic EL Element]

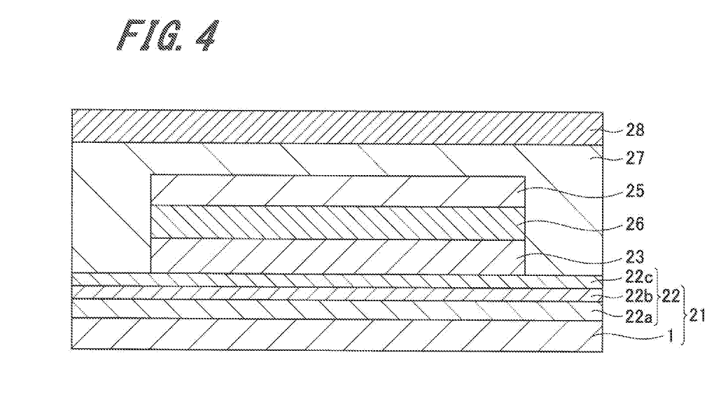

FIG. 4 shows a schematic structural view (sectional view) configuration of the organic EL element according to the present embodiment.

As shown in FIG. 4, in the organic EL element, a gas barrier film 21, a first electrode 23, a light-emitting unit 26 having an organic functional layer, and a second electrode 25 are laminated in this order. In addition, a sealing layer 27 and a sealing member 28 are provided on the second electrode 25. The organic EL element has so-called a bottom-emission-type structure in which light from the light-emitting unit 26 is extracted from the gas barrier film 21 side.

The gas barrier film 21 includes, in the similar way to the above embodiment, the resin base 1, the gas barrier layer 22 formed of the first gas barrier layer 22a, the second gas barrier layer 22b, and the third gas barrier layer 22c which are provided on the resin base 1. The electrodes are formed of the first electrode 23 and the second electrode 25, each of which constitutes a cathode and an anode of the organic EL element. The organic functional layer has at least a light-emitting layer containing an organic material, and there may be provided other layer between the light-emitting layer and the electrode.

Preferred examples of the layer configuration of various organic functional layers sandwiched between the anode and the cathode in the organic EL element are shown below, but the present invention is not limited thereto.
(1) Anode/light-emitting layer/cathode
(2) Anode/light-emitting layer/electron transport layer/cathode
(3) Anode/positive hole transport layer/light-emitting layer/cathode
(4) Anode/positive hole transport layer/light-emitting layer/electron transport layer/cathode
(5) Anode/positive hole transport layer/light-emitting layer/electron transport layer/electron injection layer/cathode
(6) Anode/positive hole injection layer/positive hole transport layer/light-emitting layer/electron transport layer/cathode
(7) Anode/positive hole injection layer/positive hole transport layer/(electron-blocking layer)/light-emitting layer/(positive hole-blocking layer)/electron transport layer/electron injection layer/cathode

Among the above, the configuration of (7) is preferably used, but the present invention is not limited thereto.

In the above representative element configurations, the layer excluding the anode and cathode is the organic functional layer. A unit mainly composed of the organic functional layer including at least the light-emitting layer is a light-emitting unit, and the organic EL element is constituted, as a whole, by sandwiching the light-emitting unit between the anode and the cathode.

In the above construction, the light-emitting layer is constituted by a mono-layer or multi-layer. When there is a plurality of the light-emitting layers, a non-light-emitting intermediate connector layer may be provided between the respective light-emitting layers.

As necessary, there may be provided a positive hole-blocking layer (positive hole barrier layer), an electron injection layer (cathode buffer layer) or the like between the light-emitting layer and the cathode, and there may be provided an electron-blocking layer (electron barrier layer), a positive hole injection layer (anode buffer layer) or the like between the light-emitting layer and the anode.

The electron transport layer is a layer having a function of transporting an electron. The electron transport layer also includes the electron injection layer, and the positive hole-blocking layer in a broad sense. In addition, the electron transport layer may be constituted of a plurality of layers.

The positive hole transport layer is a layer having a function of transporting a positive hole. The positive hole transport layer includes the positive hole injection layer, and the electron-blocking layer in a broad sense. Furthermore, the positive hole transport layer may be constituted of a plurality of layers.

### (Tandem Structure)

The organic EL element may be an element of so-called Tandem structure in which a plurality of light-emitting units 26 including at least one light-emitting layer is laminated. A representative example of an element configuration having a tandem structure is as follows.

Anode/first light-emitting unit/intermediate connector layer/second light-emitting unit/intermediate connector layer/third light-emitting unit/cathode

Here, the above first light-emitting unit, second light-emitting unit, and third light-emitting unit may be the same or different. Moreover, it may be possible that two light-emitting units are the same and the remaining one is different.

Two or more the light-emitting units 26 may be directly laminated or may be laminated via the intermediate connector layer.

Generally, the intermediate connector layer is also referred to as an intermediate electrode, an intermediate conductive layer, a charge-generating layer, an electron extraction layer, a connecting layer, an intermediate insulation layer, and may be made of a known material formulation as long as the intermediate connector layer is a layer which has a function of supplying an electron to an adjacent layer on the anode side, and supplying a positive hole to an adjacent layer on the cathode side. Examples of materials used in the intermediate connector layer include an electrically conductive inorganic compound layer such as ITO (indium tin oxide), IZO (indium zinc oxide), ZnO₂, TiN, ZrN, HfN, TiOₓ, VOₓ, CuI, InN, GaN, CuAlO₂, CuGaO₂, SrCu₂O₂, LaB₆, RuO₂, or Al, a two-layered film such as Au/Bi₂O₃, a multi-layered film such as SnO₂/Ag/SnO₂, ZnO/Ag/ZnO, Bi₂O₃/Au/Bi₂O₃, TiO₂/TiN/TiO₂, or TiO₂/ZrN/TiO₂, a fullerene such as C₆₀, an electrically conductive organic layer such as oligothiophene, and an electrically conductive organic compound layer such as metal phthalocyanine, metal-free phthalocyanine, metal porphyrin, or metal-free porphyrin, and the like, but are not limited thereto.

Preferred configuration of the light-emitting unit 26 is, for example, one in which the anode and the cathode are omitted from the representative element configuration, and the like, but is not limited thereto.

Examples of the tandem type organic EL element include elemental configurations and configuration materials described in U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087 pamphlet, Japanese Patent Laid-Open No. 2006-228712, Japanese Patent Laid-Open No. 2006-24791, Japanese Patent Laid-Open No. 2006-49393, Japanese Patent Laid-Open No. 2006-49394, Japanese Patent Laid-Open No. 2006-49396, Japanese Patent Laid-Open No. 2011-96679, Japanese Patent Laid-Open No. 2005-340187, JP Patent No. 4711424, JP Patent No. 3496681, JP Patent No. 3884564, JP Patent No. 4213169, Japanese Patent Laid-Open No. 2010-192719, Japanese Patent Laid-Open No. 2009-076929, Japanese Patent Laid-Open No. 2008-078414, Japanese Patent Laid-Open No. 2007-059848, Japanese Patent Laid-Open No. 2003-272860, Japanese Patent Laid-Open No. 2003-045676, WO 2005/094130 pamphlet, and the like, but are not limited thereto.

### [Light-Emitting Layer]

The light-emitting layer used for the organic EL element is a layer that provides a place of emitting light via an exciton produced by recombination of electrons and positive holes injected from an electrode or an adjacent layer. In the light-emitting layer, the light-emitting portion may be either within the light-emitting layer or at an interface between the light-emitting layer and an adjacent layer thereof.

A total thickness of the light-emitting layer is not particularly limited, and is determined from the viewpoint of layer homogeneity, required voltage at the time of light emission, stability of an emission color against a drive electric current, and the like.

The total thickness of the light-emitting layers is preferably adjusted to be in the range of, for example, 2 nm to 5 μm, more preferably, adjusted in the range of 2 to 500 nm, further preferably, adjusted in the range of 5 to 200 nm.

Furthermore, the thickness of each light-emitting layer is preferably adjusted to be in the range of 2 nm to 1 μm, more preferably, adjusted in the range of 2 to 200 nm, further preferably, adjusted in the range of 3 to 150 nm.

It is preferable that the light-emitting layer contains a light-emitting dopant (a light-emitting dopant compound, a dopant compound, or also simply referred to as a dopant) and a host compound (a matrix material, a light-emitting host compound, or also simply referred to as a host).

### (1. Light-Emitting Dopant)

It is preferable to use a fluorescent dopant (also referred to as a fluorescent dopant or a fluorescent compound) and a phosphorescent dopant (also referred to as a phosphorescent dopant or a phosphorescent material), as the light-emitting dopant used for the light-emitting layer. Among them, it is preferable that at least one light-emitting layer contains the phosphorescent dopant.

A concentration of the light-emitting dopant in the light-emitting layer may be arbitrarily determined on the basis of the required conditions of the specific dopant and the device to be used. A concentration of the light-emitting dopant contained may be uniform in a thickness direction of the light-emitting layer, or the light-emitting dopant may have any concentration distribution.

Furthermore, the light-emitting layer may contain a plurality of kinds of the light-emitting dopants. In the light-emitting layer, there may be used a combination of dopants each having different construction, or a combination of the fluorescent dopant and the phosphorescent dopant. Accordingly, arbitrary emission color can be obtained.

Color of light emitted by an organic EL element is specified as follows. In FIGS. 4 and 16 on page 108 of “Shinpen Shikisai Kagaku Handbook (New Edition Color Science Handbook)” (edited by The Color Science Association of Japan, Tokyo Daigaku Shuppan Kai, 1985), values determined via a spectroradiometric luminance meter CS-2000 (manufactured by Konica Minolta, Inc.) are applied to the CIE chromaticity coordinate, whereby the color is specified.

It is preferable that, in the organic EL element, one or a plurality of light-emitting layers contains a plurality of emission dopants having different emission colors and exhibits white emission. The combination of emission dopants each exhibiting a white color is not specifically limited. Examples include a combination of blue and orange, a combination of blue, green and red, and the like.

It is preferable that white in the organic EL element shows chromaticity in the CIE 1931 Color Specification System at 1, 000 cd/m² in the region of x=0.39±0.09 and y=0.38±0.08, when measurement is done to 2-degree viewing angle front luminance via the aforesaid method.

### (1.1 Phosphorescent Dopant)

The phosphorescent dopant is a compound in which emission from an excited triplet state thereof is observed. Specifically, the phosphorescent dopant is a compound which emits phosphorescence at room temperature (25° C.) and exhibits a phosphorescence quantum yield of 0.01 or more at 25° C. In the phosphorescent dopant used for the light-emitting layer, the phosphorescence quantum yield is preferably 0.1 or more.

The phosphorescence quantum yield can be measured by the method described in page 398 of Bunko II of Dai 4 Han Jikken Kagaku Koza 7 (1992, published by Maruzen Co. Ltd.). The phosphorescence quantum yield in a solution can be measured by using various solvents. In the phosphorescent dopant used for the light-emitting layer, the above phosphorescence quantum yield (0.01 or more) may be achieved by using any of the above arbitrary solvents.

There are two kinds of principles regarding emission of a phosphorescent dopant.

One is an energy transfer-type, in which an excited state of the host compound is produced by recombination of carriers on a host compound on which the carriers are transferred, and the energy is transferred to the phosphorescent dopant, with the result that emission from the phosphorescent dopant is obtained. The other is a carrier trap-type, in which a phosphorescent dopant serves as a carrier trap and recombination of carriers takes place on the phosphorescent dopant to thereby give emission from the phosphorescent dopant. In any case, the excited state energy of the phosphorescent dopant is required to be lower than the excited state energy of the host compound.

A phosphorescent dopant can be suitably selected from the known materials used for a light-emitting layer of an organic EL element.

Specific examples of the known phosphorescent dopant include compounds described in the following literatures.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991 pamphlet, WO 2008/101842 pamphlet, WO 2003/040257 pamphlet, US Patent Laid-Open No. 2006/0202194, US Patent Laid-Open No. 2007/0087321, US Patent Laid-Open No. 2005/0244673

Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290 pamphlet, WO 2002/015645 pamphlet, WO 2009/000673 pamphlet, US Patent Laid-Open No. 2002/0034656, U.S. Pat. No. 7,332,232, US Patent Laid-Open No. 2009/0108737, US Patent Laid-Open No. 2009/0039776, U.S. Pat. 6,921,915, U.S. Pat. No. 6,687,266, US Patent Laid-Open No. 2007/0190359, US Patent Laid-Open No. 2006/0008670, US Patent Laid-Open No. 2009/0165846, US Patent Laid-Open No. 2008/0015355, U.S. Pat. No. 7,250,226, U.S. Pat. No. 7,396,598, US Patent Laid-Open No. 2006/0263635, US Patent Laid-Open No. 2003/0138657, US Patent Laid-Open No. 2003/0152802, U.S. Pat. No. 7,090,928

Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714 pamphlet, WO 2006/009024 pamphlet, WO 2006/056418 pamphlet, WO 2005/019373 pamphlet, WO 2005/123873 pamphlet, WO 2005/123873 pamphlet, WO 2007/004380 pamphlet, WO 2006/082742 pamphlet, US Patent Laid-Open No. 2006/0251923, US Patent Laid-Open No. 2005/0260441, U.S. Pat. No. 7,393,599, U.S. Pat. No. 7,534,505, U.S. Pat. No. 7,445,855, US Patent Laid-Open No. 2007/0190359, US Patent Laid-Open No. 2008/0297033, U.S. Pat. No. 7,338,722, US Patent Laid-Open No. 2002/0134984, and U.S. Pat. No. 7,279,704

WO 2005/076380 pamphlet, WO 2010/032663 pamphlet, WO 2008/140115 pamphlet, WO 2007/052431 pamphlet, WO 2011/134013 pamphlet, WO 2011/157339 pamphlet, WO 2010/086089 pamphlet, WO 2009/113646 pamphlet, WO 2012/020327 pamphlet, WO 2011/051404 pamphlet, WO 2011/004639 pamphlet, WO 2011/073149 pamphlet, Japanese Patent Laid-Open No. 2012-069737, Japanese Patent Laid-Open No. 2012-195554, Japanese Patent Laid-Open No. 2009-114086, Japanese Patent Laid-Open No. 2003-81988, Japanese Patent Laid-Open No. 2002-302671, Japanese Patent Laid-Open No. 2002-363552

Among them, preferable phosphorescent dopants include organic metal complexes each containing Ir as a center metal. More preferable are complexes containing at least one coordination mode of a metal-carbon bond, a metal-nitrogen bond, a metal-oxygen bond and a metal-sulfur bond.

### [Electron Transport Layer]

The electron transport layer used for the organic EL element is composed of a material having a function of transferring an electron, and has a function of transporting an electron injected from a cathode to the light-emitting layer.

The electron transport material may be used alone or in combination of two or more kinds.

A total thickness of the electron transport layer is not particularly limited, and is usually in the range of 2 nm to 5 μm, preferably in the range of 2 to 500 nm, more preferably in the range of 5 to 200 nm.

Moreover, in the organic EL element, it is known that there is generated an interference between light directly extracted from the light-emitting layer and light extracted after being reflected at the electrode located on the opposite side of the light extraction electrode when extracting, from the electrode, the light generated in the light-emitting layer. In a case where the light is reflected at the cathode, it is possible to efficiently utilize the interference effect by adjustment of a total thickness of the electron transport layer, within the range of several nm to several μm.

On the other hand, the voltage tends to be increased when the thickness of the electron transport layer is made thick, and thus, especially in a case where the layer thickness is large, electron mobility in the electron transport layer is preferably 10⁻⁵ cm²/Vs or more.

A material used for the electron transport layer (hereinafter, also referred to as an electron transport material) may have either an injection property or a transport property of electrons, or a positive hole barrier property, and any of the conventionally known compounds can be selected and used.

Examples of the materials used for the electron transport layer include a nitrogen-containing aromatic heterocyclic derivative, an aromatic hydrocarbon ring derivative, a dibenzofuran derivative, a dibenzothiophene derivative, a silole derivative, and the like.

Examples of the above nitrogen-containing aromatic heterocyclic derivatives include a carbazole derivative, an azacarbazole derivative (a compound in which one or more carbon atoms constituting the carbazole ring are substituted with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative, and the like.

Examples of the aromatic hydrocarbon ring derivatives include a naphthalene derivative, an anthracene derivative and a triphenylene derivative, and the like.

Furthermore, there can also be used, as the electron transport material, metal complexes having, as a ligand, a quinolinol structure or dibnenzoquinolinol structure, such as tris (8-quinolinol) aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb.

In addition, a metal-free or metal phthalocyanine, or a compound whose terminal is substituted by an alkyl group or a sulfonic acid group, can also be preferably used as an electron transport material.

Furthermore, a distyryl pyrazine derivative exemplified as a material for a light-emitting layer, can also be used as an electron transport material, and in the similar way to a positive hole injection layer and a positive hole transport layer, an inorganic semiconductor such as an n-type Si and an n-type SiC can also be used as an electron transport material.

Moreover, there can be used a polymer material obtained by introducing any of these materials into a polymer side chain, or a compound obtained by using any of these materials for a polymer main chain.

In the organic EL element, there may be formed an electron transport layer of a higher n-property (electron rich), which is doped with a dopant as a guest material. Examples of the dopants include a metal compound such as a metal complex and a metal halide and other n-type dopant. Specific examples of electron transport layer having such a configuration include those described in each of the literatures of Japanese Patent Laid-Open Nos. 04-297076, 10-270172, 2000-196140, 2001-102175, as well as in J. Appl. Phys., 95, 5773 (2004).

Specific examples of the preferred known electron transport materials used for the organic EL element include compounds described in the following literatures, but are not limited thereto.

U.S. Pat. No. 6,528,187, U.S. Pat. No. 7,230,107, US Patent Laid-Open No. 2005/0025993, US Patent Laid-Open No. 2004/0036077, US Patent Laid-Open No. 2009/0115316, US Patent Laid-Open No. 2009/0101870, US Patent Laid-Open No. 2009/0179554, WO 2003/060956, WO 2008/132085, Appl. Phys.Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, Japanese Patent Laid-Open No. 2010-251675, Japanese Patent Laid-Open No. 2009-209133, Japanese Patent Laid-Open No. 2009-124114, Japanese Patent Laid-Open No. 2008-277810, Japanese Patent Laid-Open No. 2006-156445, Japanese Patent Laid-Open No. 2005-340122, Japanese Patent Laid-Open No. 2003-45662, Japanese Patent Laid-Open No. 2003-31367, Japanese Patent Laid-Open No. 2003-282270, and WO 2012/115034, and the like

More preferable electron transport materials include a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

### [Positive Hole-Blocking Layer]

The positive hole-blocking layer is a layer having a function of the electron transport layer in a broad sense. Preferably, the positive hole-blocking layer contains a material having very small ability of transporting a positive hole while having a function of transporting an electron. It is possible to enhance recombination probability of an electron and a positive hole by blocking a positive hole while transporting an electron.

Furthermore, it is possible to use the configuration of the above electron transport layer, as the positive hole-blocking layer as necessary.

The positive hole-blocking layer provided in the organic EL element is preferably provided adjacent to the cathode side of the light-emitting layer.

A thickness of the positive hole-blocking layer in the organic EL element is preferably within the range of 3 to 100 nm, and more preferably within the range of 5 to 30 nm.

The material used in the above-described electron transport layer is preferably used as a material used for the positive hole-blocking layer, and furthermore, the material used as the above-described host compound is also preferably used for the positive hole-blocking layer.

### [Electron Injection Layer]

The electron injection layer (also referred to as “cathode buffer layer”) is a layer provided between the cathode and the light-emitting layer in order to decrease a driving voltage and to enhance an emission luminance. One example of the electron injection layer is described in volume 2, chapter 2 “Electrode materials” (pp. 123-166) of “Organic EL Elements and Industrialization Front thereof (Nov. 30, 1998, published by N.T.S. Co. Ltd.)”.

In the organic EL element, the electron injection layer is provided as necessary, and as described above, is provided between the cathode and the light-emitting layer, or between the cathode and the electron transport layer.

The electron injection layer is preferably a very thin layer, and the thickness thereof is preferably within the range of 0.1 to 5 nm depending on the materials to be used. In addition, the layer may be a non-uniform layer in which the constituent material intermittently exists.

The election injection layer is detailed in Japanese Patent Laid-Open Nos. 06-325871, 09-17574 and 10-74586. Specific examples of the material preferably used in the election injection layer include: a metal represented by strontium, aluminum or the like; an alkaline metal compound represented by lithium fluoride, sodium fluoride, potassium fluoride or the like; an alkaline earth metal compound represented by magnesium fluoride, calcium fluoride or the like; a metal oxide represented by aluminum oxide; and a metal complex represented by lithium 8-hydroxyquinolate (Liq) or the like. In addition, it is also possible to use the above-described electron transport materials.

In addition, the materials used for the above electron injection layer may be used alone or in combination of two or more kinds.

### [Positive Hole Transport Layer]

The positive hole transport layer contains a material having a function of transporting a positive hole. The positive hole transport layer has a function of transporting a positive hole injected from an anode, to the light-emitting layer.

In the organic EL element, a total thickness of the positive hole transport layer is not particularly limited, and is usually within the range of 5 nm to 5 μm, preferably within the range of 2 to 500 nm, more preferably within the range of 5 to 200 nm.

A material used for the positive hole transport layer (hereinafter, also referred to as positive hole transport material) may have any of an injection property, a transport property of positive holes, and an electron barrier property.

The positive hole transport material can be preferably selected and used from the conventionally known compounds. The positive hole transport material may be used alone or in combination of two or more kinds.

Examples of the positive hole transport materials include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer obtained by introducing an aromatic amine into a side chain or a main chain, polysilane, and a conductive polymer or oligomer (e.g., PEDOT:PSS, aniline type copolymer, polyaniline and polythiophene), and the like.

Examples of the triarylamine derivatives include a benzidine type represented by α-NPD, a star burst type represented by MTDATA, a compound having fluorenone or anthracene in the triarylamine bonding core.

In addition, the hexaazatriphenylene derivative described in Japanese Unexamined Patent Application Publication No. 2003-519432 and Japanese Patent Laid-Open No. 2006-135145 can also be used as the positive hole transport material.

Furthermore, it is also possible to use the electron transport layer of a high p-property which is doped with impurities. For example, the configurations described in each of Japanese Patent Laid-Open No. 04-297076, Japanese Patent Laid-Open No. 2000-196140, and Japanese Patent Laid-Open No. 2001-102175, as well as in J. Appl. Phys., 95, 5773 (2004) can also be applied to the positive hole transport layer.

In addition, it is also possible to use so-called p-type positive hole transport materials, and inorganic compounds such as p-type Si and p-type SiC, as described in Japanese Patent Laid-Open No. 11-251067, and J. Huang et al. reference (Applied Physics Letters 80 (2002), p. 139). Moreover, the orthometal complexes having Ir or Pt as a center metal represented by Ir(ppy)₃ are also preferably used.

The above compounds can be used as the positive hole transport material, and there can be preferably used a triarylamine derivative, a carbazole derivative, an indolocarbazole derivative, an azatriphenylene derivative, an organic metal complex, a polymer or an oligomer obtained by introducing an aromatic amine into a main chain or into a side chain.

Specific examples of the positive hole transport materials used for the organic EL element include compounds described in the following literatures, as well as the above-described literatures, but are not limited thereto.

Appl. Phys. Lett. 69, 2160(1996), J. Lumin. 72-74, 985(1997), Appl. Phys. Lett. 78, 673(2001), Appl. Phys. Lett. 90, 183503(2007), Appl. Phys. Lett. 51, 913(1987), Synth. Met. 87, 171(1997), Synth. Met. 91, 209(1997), Synth. Met. 111, 421 (2000), SID Symposium Digest, 37, 923 (2006), J. Mater. Chem. 3, 319(1993), Adv. Mater. 6, 677(1994), Chem. Mater. 15, 3148(2003), US Patent Laid-Open No. 2003/0162053, US Patent Laid-Open No. 2002/0158242, US Patent Laid-Open No. 2006/0240279, US Patent Laid-Open No. 2008/0220265, U.S. Pat. No. 5,061,569, WO 2007/002683, WO 2009/018009, EP 650955, US Patent Laid-Open No. 2008/0124572, US Patent Laid-Open No. 2007/0278938, US Patent Laid-Open No. 2008/0106190, US Patent Laid-Open No. 2008/0018221, WO 2012/115034, Japanese Unexamined Patent Application Publication No. 2003-519432, Japanese Patent Laid-Open No. 2006-135145, and U.S. patent application Ser. No. 13/585981.

### [Electron-Blocking Layer]

The electron-blocking layer is a layer having a function of the positive hole transport layer in a broad sense. Preferably, the electron-blocking layer is a layer contains a material having very small ability of transporting an electron while having a function of transporting a positive hole. It is possible to enhance recombination probability of an electron and a positive hole by blocking an electron while transporting a positive hole.

Furthermore, it is possible to use the configuration of the above positive hole transport layer, as the electron-blocking layer as necessary. The electron-blocking layer provided in the organic EL element is preferably provided adjacent to the anode side of the light-emitting layer.

A thickness of the electron-blocking layer is preferably within the range of 3 to 100 nm, more preferably within the range of 5 to 30 nm.

The material used in the above-described positive hole transport layer is preferably used as a material used for the electron-blocking layer. In addition, the material used as the above-described host compound is also preferably used for the electron-blocking layer.

### [Positive Hole Injection Layer]

The positive hole injection layer (also referred to as “anode buffer layer”) is a layer provided between the anode and the light-emitting layer in order to decrease a driving voltage and to enhance an emission luminance. One example of the positive hole injection layer is described in volume 2, chapter 2 “Electrode materials” (pp. 123-166) of “Organic EL Elements and Industrialization Front thereof (Nov. 30, 1998, published by N.T.S. Co. Ltd.)”.

The positive hole injection layer is provided as necessary, and as described above, is provided between the anode and the light-emitting layer, or between the anode and the positive hole transport layer.

The positive hole injection layer is also described in detail in Japanese Patent Laid-Open Nos. 09-45479, 09-260062 and 08-288069.

Materials used for the positive hole injection layers include, for example, materials used in the above-described positive hole transport layer. Among them, preferable examples include: a phthalocyanine derivative represented by copper phthalocyanine; a hexaazatriphenylene derivative described in Japanese Unexamined Patent Application Publication No. 2003-519432 and Japanese Patent Laid-Open No. 2006-135145; a metal oxide represented by vanadium oxide; a conductive polymer such as amorphous carbon, polyaniline (emeraldine) and polythiophene; an orthometalated complex represented by tris(2-phenylpyridine) iridium complex; and a triarylamine derivative, and the like.

The material used for the above-described positive hole injection layer may be used alone or in combination of two or more kinds.

### [Other Additives]

The organic functional layer constituting the organic EL element may further contain other additives.

Examples of the other additives include halogen elements such as bromine, iodine and chlorine, and a halogenated compound, a compound, complex and salt of an alkali metal, an alkaline earth metal and a transition metal such as Pd, Ca and Na.

A content of the additives can be arbitrarily determined, and preferably 1, 000 ppm or less with respect to the total mass of the layer contained, more preferably 500 ppm or less, and further preferably 50 ppm or less.

However, the content is not necessarily within the above range depending on the purpose of enhancing the transporting ability of electrons or positive holes, or of facilitating energy transport of exciton.

### [Formation Method of Organic Functional Layer]

The formation method of the organic functional layer of the organic EL element (positive hole injection layer, positive hole transport layer, light-emitting layer, positive hole-blocking layer, electron transport layer, and electron injection layer) will be explained.

Formation methods of the organic functional layer are not particularly limited, and the organic functional layer can be formed by known methods such as a vacuum vapor deposition method and a wet method (wet process).

Examples of the wet process include a spin coating method, a cast method, an inkjet method, a printing method, a die coating method, a blade coating method, a roll coating method, a spray coating method, a curtain coating method, and an LB method (Langmuir Blodgett method), and the like. From the viewpoint of easily obtaining a uniform thin layer and of high productivity, preferable are methods highly suited to roll-to-roll methods such as a die coating method, a roll coating method, an inkjet method, and a spray coating method.

Examples of liquid media that dissolve or disperse a material of the organic functional layer in the wet process include ketones such as methyl ethyl ketone and cyclohexanone, aliphatic esters such as ethyl acetate, halogenated hydrocarbons such as dichlorobenzene, aromatic hydrocarbons such as toluene, xylene, mesitylene, and cyclohexylbenzene, aliphatic hydrocarbons such as cyclohexane, decalin, and dodecane, and organic solvents such as DMF and DMSO.

In addition, dispersion can be carried out by dispersion methods such as an ultrasonic dispersion method, a high shearing dispersion method and a media dispersion method.

In a case where the vapor deposition method is adopted for forming each layer of the organic functional layer, the vapor deposition conditions are different depending on the compounds to be used, and generally, appropriate selection is desirably carried out within the ranges of heating temperature of boat: 50 to 450° C., level of vacuum: 10⁻⁶ to 10⁻² Pa, vapor deposition rate: 0.01 to 50 nm/sec, temperature of substrate: −50 to 300° C., and layer thickness: 0.1 nm to 5 μm, preferably 5 to 200 nm.

Although formation of the organic EL element is preferably consistently carried out from the organic functional layer to the cathode by one-time vacuuming, a different deposition method may be employed by extraction in the middle. In such a case, the operation is preferably carried out under a dry inert gas atmosphere.

Moreover, a different formation method may be applied to each layer.

### [First Electrode]

There is used, as the first electrode 23, an electrode material having a high work function (4 eV or more, preferably 4.3 V or more) such as a metal, an alloy, an electrically conductive compound, or a mixture thereof.

Examples of such electrode materials include a metal such as Au or Ag, an alloy thereof, an electrically conductive transparent material such as CuI, indium tin oxide (ITO), SnO₂ or ZnO.

In addition, a material capable of fabricating an amorphous transparent conductive film such as IDIXO (In₂O₃—ZnO) may also be used.

In the first electrode 23, thin films of these electrode materials may be formed by a method such as vapor deposition or sputtering, and a pattern having a desired shape maybe formed by photolithography. Furthermore, in a case where high patterning accuracy is not required so much (approximately 100 μm or more), a certain pattern may be formed via a mask having a desired shape at the time of vapor deposition or sputtering of the electrode material.

Alternatively, in a case where a material capable of being coated such as an electrically conductive organic compound is used, a wet film forming method such as a printing method or a coating method can also be used.

In a case where the emitted light is extracted from the first electrode 23 side, the light transmittance is desired to be more than 10%.

In addition, the sheet resistance as the first electrode 23 is preferably several hundred Q/sq or less.

Furthermore, the thickness of the first electrode 23 is selected within the range of 10 nm to 1 μm, preferably within the range of 10 to 200 nm, depending on the material.

Particularly, the first electrode 23 is a layer containing silver as a main component, and is preferably composed of silver or an alloy containing silver as a main component.

Examples of the formation methods of the first electrode 23 include: a method using a wet process such as an application method, an inkjet method, a coating method, or a dipping method; a method using a dry process such as a vapor deposition method (resistance heating, EB method, etc.), a sputtering method or a CVD method; and the like. Among them, the vapor deposition method is preferably applied.

Examples of the alloys constituting the first electrode 23 and being mainly composed of silver (Ag) include silver magnesium (AgMg), silver copper (AgCu), silver palladium (AgPd), silver palladium copper (AgPdCu), silver indium (AgIn), and the like.

The first electrode 23 as described above may have a configuration in which layers of silver or layers of the alloy mainly composed of silver are laminated dividedly into a plurality of layers, as necessary.

Furthermore, the first electrode 23 preferably has a thickness of 20 nm or less, and within the range of 4 to 15 nm. When the thickness is 15 nm or less, it is preferable because an absorbing component and a reflecting component in the layer may be decreased to maintain the light permeability of the transparent barrier film. In addition, when the thickness is 4 nm or more, the electric conductivity of the layer can be ensured.

Note that, when forming a layer composed of silver as a main component as the first electrode 23, other electrically conductive layer containing Pd or the like, and an organic layer of a nitrogen compound, a sulfur compound or the like is provided as the under layer of the first electrode 23. It is possible to improve the film forming ability of the layer composed of silver as a main component, to lower the resistance of the first electrode 23, and to improve the light transmittance of the first electrode 23, by forming the under layer.

### [Second Electrode]

There is used, as the second electrode 25, an electrode material having a low work function (4 eV or less) such as a metal (referred to as an electron-injecting metal), an alloy, an electrically conductive compound, or a mixture thereof.

Specific examples of such electrode materials as described above include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, a rare earth metal, and the like.

Among them, from the viewpoint of electron injection property and durability against oxidation, preferred examples are a mixture of the electron-injecting metal and a secondary metal that is a metal having a work function higher than that of the electron-injecting metal and being more stable, such as a magnesium/silver mixture, a magnesium/aluminum mixture, a magnesium/indium mixture, an aluminum/aluminum oxide (Al₂O₃) mixture, a lithium/aluminum mixture, aluminum, and the like.

The second electrode 25 can fabricate the above-described electrode material by a method such as vapor deposition or sputtering. In addition, the sheet resistance of the second electrode 25 is preferably several hundred Ω/sq or less. Furthermore, the thickness of the second electrode 25 is usually selected within the range of 10 nm to 5 μm, preferably within the range of 50 nm to 200 nm.

In addition, when the above metal is fabricated, in the second electrode 25, having a thickness in the range of 1 to 20 nm, the electrically conductive transparent materials mentioned in the explanation of the first electrode is fabricated thereon, and thus a transparent or translucent second electrode 25 can be fabricated. It is possible to fabricate an element in which both of the first electrode 23 and the second electrode 25 both have a light-transmitting property through the utilization of this technique.

### [Sealing Layer]

The organic EL element is sealed in a solid manner by sticking a sealing member 28 onto one surface of the gas barrier film 21 in which the gas barrier layer 22 is formed, via a sealing layer 27 covering the first electrode 23, the light-emitting unit 26 and the second electrode 25.

The solid sealing of the organic EL element is formed in an integrated manner by applying an uncured resin material onto several portions of the surfaces to be stuck of the sealing member 28 or the gas barrier film 21, by compressing the sealing member 28 and the gas barrier film 21 via these resin materials, and then by curing the resin material.

The sealing layer 27 is provided in a state of covering as least the light-emitting unit 26, and is provided in a state of exposing the terminal portions (not shown) of the first electrode 23 and the second electrode 25. Furthermore, a configuration may be such that an electrode is provided on the sealing member 28, and the electrode is electrically communicated with the terminal portions of the first electrode 23 and the second electrode 25 of the organic EL element.

The sealing layer 27 is constituted by the resin material (resin sealing layer) for bonding the gas barrier film 21 and the sealing member 28.

Moreover, an inorganic material (inorganic sealing layer) may also be used in addition to the resin material (resin sealing layer). For example, a configuration may be such that, after the first electrode 23, the light-emitting unit 26 and the second electrode 25 is covered with the inorganic sealing layer, the sealing member 28 and the gas barrier film 21 are bonded by the resin sealing layer.

### [Resin Sealing Layer]

The resin sealing layer is used for fixing the sealing member 28 on the gas barrier film 21 side. In addition, the resin sealing layer is used as a sealing agent for sealing the first electrode 23, the light-emitting unit 26 and the second electrode 25 which are sandwiched between the sealing member 28 and the gas barrier film 21.

In order to bond the sealing member 28 to the gas barrier film 21, it is preferable to adhere by the use of an optional curable resin sealing layer.

As the resin sealing layer, a preferable adhesive can be appropriately selected from the viewpoint of enhancing the adhesion to the adjacent sealing member 28, the gas barrier film 21, and the like.

A heat-curable resin is preferably used as the resin sealing material.

There can be used, as the heat-curable resin, for example, a resin containing, as main components, a compound having an ethylenic double bond at the end or a side chain of a molecule, and a heat polymerization initiator, or the like.

More specifically, there can be used a heat-curable resin composed of an epoxy-based resin, an acrylic resin, and the like. Furthermore, a molten-type heat-curable resin may be used depending on the sticking apparatus and the curing treatment apparatus used in the production steps of the organic EL element.

In addition, a photocurable resin is preferably used as the resin sealing layer.

Examples include a photo radically polymerizable resin having various (meth)acrylate as a main component such as polyester (meth)acrylate, polyether (meth)acrylate, epoxy (meth)acrylate or polyurethane (meth)acrylate, a photocationic polymerizable resin having a resin as a main component such as epoxy, vinyl ether, or the like, a thiol-ene adduct resin, and the like. Among the photocurable resins, the photocationic polymerizable resin such as the epoxy resin is preferable because of low shrinkage of the cured article, low out gas, and excellent long reliability.

Furthermore, a chemically curable (two liquids mixing) resin can be used as the resin sealing layer like this. Moreover, a hot-melt type polyamide, polyester or polyolefin can be used. In addition, an ultraviolet ray curable epoxy resin of cation curable type can be used.

Note that there is a case where the organic material of the organic EL element is degraded by heat treatment. Therefore, it is preferable to use a resin material which can be bonded and cured at a temperature from room temperature to 80° C.

### [Inorganic Sealing Layer]

The inorganic sealing layer is formed so as to cover, on the gas barrier film 21 having the gas barrier layer 22, portions other than the portion where the first electrode 23, the light-emitting unit 26 and the second electrode 25 are placed.

The inorganic sealing layer is a member that seals the first electrode 23, the light-emitting unit 26 and the second electrode 25 together with the resin sealing layer. Accordingly, preferable material to be used for the inorganic sealing layer is a material having a function of suppressing the intrusion of moisture, oxygen and the like, which degrade the first electrode 23, the light-emitting unit 26 and the second electrode 25.

In addition, preferable material to be used for the inorganic sealing layer is a material that is excellent in bonding property to the first electrode 23, the light-emitting unit 26 and the second electrode 25, because of having a configuration of the direct contact with the first electrode 23, the light-emitting unit 26 and the second electrode 25.

The inorganic sealing layer is preferably formed by a compound, having a high sealing property, such as an inorganic oxide, an inorganic nitride or an inorganic carbide.

Specifically, the inorganic sealing layer can be formed by SiOₓ, Al₂O₃, In₂O₃, TiOₓ, ITO (tin indium oxide), AlN, Si₃N₄, SiOₓN, TiOₓN, SiC, and the like.

The inorganic sealing layer can be formed by a known procedure such as a sol-gel method, a vapor deposition method, a CVD, an ALD (Atomic Layer Deposition), a PVD, a sputtering method, and the like.

Moreover, in the inorganic sealing layer, there can be separately formed the compositions of silicon oxide, an inorganic oxide having silicon oxide as a main component, or a mixture of an inorganic carbide, an inorganic nitride, an inorganic sulfide and an inorganic halide such as an inorganic oxide nitride or an inorganic oxide halide, by selection of the conditions such as the organic metal compound of a raw material (also referred to as a primary material), the decomposed gas, the decomposing temperature and the applied electric power, in the atmospheric pressure plasma method.

For example, silicon oxide is generated by using a silicon compound as the raw material and oxygen as the decomposition gas, and silicon nitride oxide is generated by using a silazane as the raw material. In the space of plasma, extremely active charged particles or active radicals exist in high density, and thus multiple steps of chemical reaction are accelerated at very high speed in the plasma space, and elements in the plasma space are converted to the chemically stable compound in an extremely short time.

The raw material for forming the inorganic sealing layer may have any of the conditions of gas, liquid and solid at room temperature under normal pressure as long as the raw material is a silicon compound. The gas can be directly introduced into the discharge space, and the liquid or solid is used after being vaporized by a procedure such as heating, bubbling, reduction of pressure or ultrasonic irradiation.

Moreover, the raw material maybe used after dilution with a solvent, and an organic solvent such as methanol, ethanol, n-hexane and a mixture thereof can be used for such the solvent. Note that, since the solvent is decomposed into a molecular or an atomic state during the plasma discharge treatment, the influence of the solvent can be almost ignored.

Examples of the silicon compounds include silane, tetramethoxysilane, tetraethoxysilane, tetran-propoxysilane, tetraisopropoxsilane, tetran-butoxysilane, tetrat-butoxysilane, dimethyldimethoxysilane, dimethyldiethoxysilane, diethyldimethoxysilane, diphenyldimethoxysilane, methyltriethoxysilane, ethyltrimethoxysilane, phenyltriethoxysilane, (3,3,3-trifluoropropyl)trimethoxysilane, hexamethyldisyloxane, bis(dimethylamino)dimethylsilane, bis(dimethylamino)methylvinylsilane, bis(ethylamino)dimethylsilane, N,O-bis(trimethylsilyl)acetoamide, bis(trimethylsilyl)carbodiimide, diethylaminotrimethylsilane, dimethylaminodimethylsilane, hexamethyldisilazane, heaxamethylcyclotrisilazane, heptamethyldisilazane, nonamethyltrisilazane, octamethylcyclotetrasilazane, tetrakisdimethyaminosilane, tetraisocyanatesilane, tetramethyldisilazane, tris(dimethylamino)silane, triethoxyfluorosilane, allyldimethylsilane, allyltrimethylsilane, benzyltrimethylsilane, bis(trimethylsilyl)acetylene, 1,4-bistrimethylsilyl-1,3-butadiine,di-t-butylsilane, 1,3-disilabutane, bis(trimethylsilyl)methane, cyclopentanedienyltrimethylsilane, phenyldimethylsilane, phenyltrimethylsilane, propargyltrimethylsilane, tetramethylsilane, trimethylsilylacetylene, 1-(trimethylsilyl)-1-propine, tris(trimehtylsilyl)methane, tris(trimethylsilyl)silane, vinyltrimethylsilane, hexamethyldisilane, octamethylcyclotetrasiloxane, tetramethylcyclotetrasiloxane, heaxmethylcycrotetrasiloxane, M-silicate 51, and the like.

Moreover, examples of the decomposition gases for decomposing the raw material gas containing silicon to thereby give the inorganic sealing layer include hydrogen gas, methane gas, acetylene gas, carbon monoxide gas, carbon dioxide gas, nitrogen gas, ammonium gas, nitrous oxide gas, nitrogen oxide gas, nitrogen dioxide gas, oxygen gas, steam, fluorine gas, hydrogen fluoride, trifluoroalcohol, trifluorotoluene, hydrogen sulfide, sulfur dioxide, carbon disulfide, chlorine gas, and the like.

The inorganic sealing layer containing silicon oxide, nitride, carbide and the like can be obtained by selection of the above raw material gas that contains silicon and the decomposition gas.

In the atmospheric pressure plasma method, the reactive gas is mixed with a discharge gas that easily becomes a plasma state, and then the gas is sent to the plasma discharge generation apparatus.

Nitrogen gas and/or an atom of Group 18 of periodic table such as helium, neon, argon, krypton, xenon or radon are used as such the discharge gas. Among them, particularly, nitrogen, helium and argon are preferably used.

The discharge gas and the reactive gas are mixed, and the resultant mixed was then supplied into the atmospheric pressure plasma discharge (plasma generation) apparatus as a thin film forming (mixed) gas, to thereby form the layer. Although the ratio of the discharge gas to the reactive gas is different depending on properties of a film to be obtained, the reactive gas is supplied in a ratio of the discharge gas to whole mixture of the gases of at least 50%.

### [Sealing Member]

A sealing member 28 is a material for covering the organic EL element, and a plate-like (film-like) sealing member 28 is fixed to the gas barrier film 21 side by a sealing resin layer 27.

Specific examples of the plate-like (film-like) sealing members 28 include a glass substrate and a polymer substrate, and these substrate materials may be used in the form of thin film.

Examples of the glass substrates can particularly include soda lime glass, barium strontium-containing glass, lead glass, alminosilicate glass, borosilicate glass, barium borosilicate glass, quartz, and the like.

In addition, examples of the polymer substrates can include polycarbonate, acryl, polyethylene terephthalate, polyethersulfide, polysulfone, and the like.

Moreover, a metal foil on which a resin film is laminated (polymer film) is preferably used as the sealing member 28. Although the metal foil on which a resin film is laminated cannot be used as the substrate on the light extraction side, the foil is a sealing material having a low cost and a low moisture permeability. Accordingly, the foil is suitable for the sealing member 28 when it is not intended for light extraction.

Note that the metal foil refers to a foil or film of a metal formed by rolling method or the like, unlike a metallic thin film formed by sputtering or vapor deposition, and an electrically conductive film formed of a flowable electrode material such as an electrically conductive paste.

The metal foil is not particularly limited to the kind of the metal, and examples thereof include copper (Cu) foil, aluminum (Al) foil, gold (Au) foil, brass foil, nickel (Ni) foil, titanium (Ti) foil, copper alloy foil, stainless steel foil, tin (Sn) foil and high-nickel allow foil, and the like. Among these various metal foils, particularly preferable metal foil is the Al foil.

The thickness of the metal foil is preferably within the range of 6 to 50 μm. When the thickness is within the range of 6 to 50 μm, the generation of pin holes at the time of use can be prevented, and the required gas barrier properties (moisture permeability, oxygen permeability) can be obtained.

In the metal foil with the resin film laminated thereon, various materials disclosed in the “New Development in the Functional Packaging Materials” (Toray Research Center) can be used as the resin film.

There can be used, for examples, a polyethylene-based resin, a polypropylene-based resin, a polyethylene terephthalate-based resin, a polyamide-based resin, an ethylene-vinyl alcohol copolymer-based resin, an ethylene-vinyl acetate-based copolymer-based resin, an acrylonitryl-butadiene copolymer-based resin, a cellophane-based resin, a Vinylon-based resin, and a polyvinylidene chloride-based resin, and the like.

The polypropylene-based resin and Nylon-based resin may be stretched, or the polyvinylidene chloride-based resin may be coated. In addition, the polyethylene-based resin of either low density or high density may be used.

The sealing member 28 preferably has an oxygen permeability measured by the method in accordance with JIS-K-7126-1987 of 1×10⁻³ ml/(m²·24 h·atm) or less and a water vapor permeability (25±0.5° C., relative humidity (90±2)% RH)measured by the method in accordance with JIS-K-7129-1992 of 1×10⁻³ g/(m²·24 h) or less.

In addition, the above substrate material may be processed in the form of a concave plate for use as the sealing member 28. In such a case, the above substrate member is subjected to processing such as sandblast processing or chemical etching processing to thereby form concave portions.

Furthermore, a metallic material may also be used without being limited to those. Examples of the metallic materials include one or more of kinds of metals or alloys selected from the group consisting of stainless steel, iron, copper, aluminum, magnesium, nickel, zinc, chromium, titanium, molybdenum, silicon, germanium and tantalum. The whole light-emitting panel in which the organic EL element is provided can be made thinner by the use of the metallic material made into thin film as the sealing member 28.

### [Uses]

The organic EL elements can be applied to electronic devices such as display devices, displays, and various light-emitting sources.

Examples of the light-emitting sources include a lighting device such as a home lighting device or a car lighting device, a backlight for a timepiece or a liquid crystal, a signboard for advertisement, a light source for a signal, a light source for an optical storage medium, a light source for an electrophotographic copier, a light source for an optical communication processor, a light source for an optical sensor, and the like, but are not limited thereto. Particularly, it can be effectively used for applications as a backlight for a liquid crystal display device and as a light source.

In the organic EL element, patterning may be carried out at the time of film deposition by the use of a metal mask or an inkjet printing method, and the like, as necessary. In case of the patterning, only the electrode may be patterned, the electrode and the light-emitting layer may be patterned, or the entire element may be patterned. It is possible to use the conventional known methods in the fabrication of the element.

### EXAMPLE 1

### [Fabrication of Gas Barrier Film]

Hereinafter, the present invention will be specifically explained by referring to Examples.

The respective gas barrier films of Samples 101 to 112 were fabricated. In the following Table 2, configurations of the respective layers in the gas barrier films of Samples 101 to 112 are shown.

### [Sample 101]

A gas barrier film of Sample 101 was fabricated by forming the first gas barrier layer, the second gas barrier layer and the third gas barrier layer on one surface of the resin base, by the conditions below.

### (Resin Base)

There was used a polyethylene terephthalate film having a thickness of 25 μm in which the both surfaces were subjected to easy adhesion processing (Teijin Tetron Film G2P2 manufactured by Teijin DuPont Films Japan Limited, hereinafter referred to as PET) as the resin base. Furthermore, the surface of the resin base was subjected to the corona discharge treatment by using a corona discharge device AGI-080 (manufactured by KASUGA ELECTRIC WORKS LTD.). The corona discharge was carried out, at the time of the corona discharge treatment, for 10 seconds under the condition that the gap between a discharge electrode of the corona discharge device and the film was set to 1 mm, and that the treatment output was 600 mW/cm².

### (Formation of First Gas Barrier Layer)

The first gas barrier layer was fabricated by using the roll-to-roll type CVD deposition apparatus having the first deposition portion and the second deposition portion and was constructed by connecting two apparatuses having a deposition portion composed of a pair of opposite rolls described in Japanese Patent No. 4268195 (referring to FIG. 3) according to the plasma CVD method (PECVD). There was formed, by the use of the apparatus, the first gas barrier layer having a thickness of 200 nm on the resin base under the following conditions.

In the first gas barrier layer, there were adopted an effective deposition width of 1,000 mm and a conveying speed of 7.0 m/min, and, at the first deposition portion and the second deposition portion, there were adopted respective supply amount of the material gas (HMDSO), supply amount of oxygen gas, degree of vacuum and applied electric power in the following conditions.

The thickness of the deposition was adjusted by a number of times of film deposition (number of passes through the apparatus). Although the second pass was conveyed in the direction where the resin base was wound back in comparison with the first pass, the deposition portion through which the base passed first was set to the first deposition portion, and the deposition portion through which the base passed next was set to as the second deposition portion, in a case where the direction of the pass is different. The thickness was obtained by the cross-sectional TEM observation.

As to the other conditions, the power source frequency was 84 kHz, and the temperatures of the deposition rolls were all 30° C.

The deposition conditions of the first deposition portion and the second deposition portion are shown below.
First deposition portion

Conveying speed: 7.0 m/min

Supply amount of material gas (HMDSO): 150 sccm

Supply amount of oxygen gas: 500 sccm

Degree of vacuum: 1.5 Pa

Applied electric power: 4.5 kW
Second deposition portion

Conveying speed: 7.0 m/min

Supply amount of material gas: 150 sccm

Supply amount of oxygen gas: 500 sccm

Degree of vacuum: 1.5 Pa

Applied electric power: 4.5 kW

### (Formation of Second Gas Barrier Layer)

Next, the second gas barrier layer was formed on the first gas barrier layer. The second gas barrier layer was formed by applying a coating liquid containing the following polysilazane to thereby form a coating film, and then modifying the coating film by vacuum ultraviolet ray irradiation.

First, a coating liquid was prepared by mixing a dibutyl ether solution containing perhydropolysilazane (PHPS) in an amount 20% mass (NN120-20 manufactured by AZ Electronic Materials, Co., Ltd.) and a dibutyl ether solution containing perhydropolysilazane in an amount 20% mass containing an amine catalyst (N,N,N′,N′-tetramethyl-1,6-diaminohexane (TMDAH)) (NAX120-20 manufactured by AZ Electronic Materials, Co., Ltd.) in a weight ratio of 4:1 (mass ratio), and by further appropriately diluting the mixture with dibutyl ether for adjusting the dry film thickness.

Preparation was carried out by cutting, in a sheet-like shape, the resin base where the first gas barrier layer was formed. The coating film was formed on the surface of the first gas barrier layer having been already formed. The coating liquid was applied by a spin coating method so that a dry film thickness was 470 nm, and was then dried at 80° C. for 2 minutes. Next, the dried coating film was subjected to vacuum ultraviolet ray irradiation treatment under the conditions of the oxygen concentration 1.0 (% by volume) and the irradiation energy 3.0 (J/cm²) by the use of a Xe excimer lamp of a wavelength of 172 nm, and thus there was formed the second gas barrier layer in which the entire region having a thickness of 470 nm was the region (b).

There was obtained, by the use of the following XPS analysis, the composition distribution in the thickness direction of the region (b) with which the second gas barrier layer was provided.
XPS analysis conditions

Apparatus: QUANTERASXM manufactured by ULVAC-PHI, INCORPORATED

X-Ray source: Monochromatic Al-Kα

Measurement region: Si2p, C1s, N1s, O1s

Sputtering ion: Ar (2 keV)

Depth profile: The measurement was repeated after sputtering for a given period of time. The sputtering period of time is adjusted so that a thickness in terms of SiO₂ becomes about 2.8 nm in one measurement.

Quantification: Quantification is carried out by obtaining the background according to the Shirley method, and by using the relative sensibility coefficient method, from the obtained peak area. The data processing is performed by the use of MultiPak manufactured by ULVAC-PHI, INCORPORATED.

According to the above procedures, there was obtained a first data of the profile of the composition distribution in the thickness direction of the second gas barrier layer. The obtained profile of the composition distribution in the thickness direction is corrected by the use of the actual thickness data obtained from the TEM image to thereby give the composition distribution in the thickness direction, with the result that thickness of the region (b) was obtained.

The thickness of the second gas barrier layer was obtained by the cross-sectional TEM observation.

### (Formation of Third Gas Barrier Layer)

Subsequently, the third gas barrier layer was formed on the second gas barrier layer.

The third gas barrier layer was formed by the use of a magnetron sputtering apparatus under the following conditions.
Deposition conditions

Target: Oxygen-deficient type niobium pentoxide target

Sputtering electric power: DC 5 W/cm²

Process gas: Ar, O₂ (O₂ partial pressure 15%)

Gas pressure: 0.3 Pa

Deposition thickness: 100 nm

### [Sample 102]

A gas barrier film of Sample 102 was fabricated in the similar way to that in Sample 101 except that the thickness of the second gas barrier layer was 750 nm (the whole area being the region (b)).

### [Sample 103]

A gas barrier film of Sample 103 was fabricated in the similar way to that in Sample 101 except that the thickness of the second gas barrier layer was 60 nm (the whole area being the region (b)).

### [Sample 104]

A gas barrier film of Sample 104 was fabricated in the similar way to that in Sample 101 except that the deposition conditions of the third gas barrier layer were changed to the following conditions.
Deposition conditions

Target: Tantalum target

Sputtering electric power: DC 5 W/cm²

Process gas: Ar, O₂ (O₂ partial pressure 20%)

Gas pressure: 0.3 Pa

Deposition thickness: 50 nm

### [Sample 105]

A gas barrier film of Sample 105 was fabricated in the similar way to that in Sample 101 except that the deposition conditions of the third gas barrier layer were changed to the following conditions.
Deposition conditions

Target: Oxygen-deficient type titanium oxide target

Sputtering electric power: DC 5 W/cm²

Process gas: Ar, O₂ (O₂ partial pressure 3%)

Gas pressure: 0.3 Pa

Deposition thickness: 100 nm

### [Sample 106]

A gas barrier film of Sample 106 was fabricated in the similar way to that in Sample 101 except that the deposition conditions of the third gas barrier layer were changed to the following conditions.
Deposition conditions

Target: Zirconium target

Sputtering electric power: DC 5 W/cm²

Process gas: Ar, O₂ (O₂ partial pressure 20%)

Gas pressure: 0.3 Pa

Deposition thickness: 100 nm

### [Sample 107]

A gas barrier film of Sample 107 was fabricated in the similar way to that in Sample 101 except that the first gas barrier layer having a dry film thickness of 250 nm was formed by applying an energy to a coating film obtained by applying and drying a coating liquid containing the polysilazane in the similar conditions to those in the second gas barrier layer of Sample 101.

Namely, in the gas barrier film of Sample 107, the first gas barrier layer and the second gas barrier layer were both layers formed by applying an energy to a coating film which was obtained by applying and drying a coating liquid containing the polysilazane, and thus, two layers formed by applying an energy to a coating film which was obtained by applying and drying a coating liquid containing the polysilazane were laminated.

### [Sample 108]

A gas barrier film of Sample 108 was fabricated in the similar way to that in Sample 101 except that the first gas barrier layer was formed by the use of a magnetron sputtering apparatus under the following conditions.
Deposition conditions

Target: Polycrystal SiO₂

Sputtering electric power: DC 5 W/cm²

Process gas: Ar, O₂ (O₂ partial pressure 20%)

Gas pressure: 0.3 Pa

Deposition thickness: 250 nm

### [Sample 109]

A gas barrier film of Sample 109 was fabricated in the similar way to that in Sample 101 except that the third gas barrier layer was not fabricated. Therefore, the gas barrier film of Sample 109 is constituted of the resin base, the first gas barrier film and the second gas barrier layer.

### [Sample 110]

A gas barrier film of Sample 110 was fabricated in the similar way to that in Sample 101 except that the thickness of the second gas barrier layer was 35 nm.

### [Sample 111]

A gas barrier film of Sample 111 was fabricated in the similar way to that in Sample 101 except that the thickness of the second gas barrier layer was 1100 nm (the whole area being the region (b)).

### [Sample 112]

A gas barrier film of Sample 112 was fabricated in the similar way to that in Sample 111 except that the third gas barrier layer was formed under the following deposition conditions.
Deposition conditions

Target: Polycrystal SiO₂

Sputtering electric power: DC 5 W/cm²

Process gas: Ar, O₂ (O₂ partial pressure 20%)

Gas pressure: 0.3 Pa

Deposition thickness: 100 nm

### [Evaluation of Gas Barrier Film]

The following evaluation was carried out as to the fabricated Sample of the gas barrier film.

### (Continuous Bending Test)

The continuous bending test was conducted by continuous reciprocating bending of the gas barrier film 1,000 times at a curvature of a bending diameter 6 mmφ at room temperature, and the difference in the degrees of degradation between the bent portion and the not bent portion was evaluated on a scale of 1 to 5 [(good) 5>1 (bad)].

The configurations of the above gas barrier films of Samples 101 to 112 and the respective evaluation results are shown in Table 2.

TABLE 2

| | First | | Second | | Third | | | |
|---|---|---|---|---|---|---|---|---|
| | barrier layer | | barrier layer | | barrier layer | | | |
| | Production | Thickness | | Thickness | | Thickness | Continuous | |
| | method | nm | Material | nm | Composition | nm | bending | |
| 101 | Plasma CVD | 200 | PHPS | 470 | Nb₂O₅ | 100 | 5 | Present invention |
| 102 | Plasma CVD | 200 | PHPS | 750 | Nb₂O₅ | 100 | 5 | Present invention |
| 103 | Plasma CVD | 200 | PHPS | 60 | Nb₂O₅ | 100 | 4 | Present invention |
| 104 | Plasma CVD | 200 | PHPS | 470 | Ta₂O₅ | 50 | 5 | Present invention |
| 105 | Plasma CVD | 200 | PHPS | 470 | TiO₂ | 100 | 4 | Present invention |
| 106 | Plasma CVD | 200 | PHPS | 470 | ZrO₂ | 100 | 4 | Present invention |
| 107 | Wet-Modification | 250 | PHPS | 470 | Nb₂O₅ | 100 | 4 | Present invention |
| 108 | Sputter | 250 | PHPS | 470 | Nb₂O₅ | 100 | 4 | Present invention |
| 109 | Plasma CVD | 200 | PHPS | 470 | None | — | 1 | Comparative Example |
| 110 | Plasma CVD | 200 | PHPS | 35 | Nb₂O₅ | 100 | 3 | Comparative Example |
| 111 | Plasma CVD | 200 | PHPS | 1100 | Nb₂O₅ | 100 | 3 | Comparative Example |
| 112 | Plasma CVD | 200 | PHPS | 1100 | SiO₂ | 100 | 2 | Comparative Example |

As shown in Table 2, Samples 101 to 108 in which the first to third gas barriers satisfy the requirements of the above embodiment are excellent in the result of the continuous bending test. Particularly, Samples containing the oxide of Nb or Ta as the third gas barrier layer are excellent in the result of the continuous bending test.

As to Sample 110 and Sample 111 in which the thickness of the region (b) of the second gas barrier layer is outside the range of 50 to 1,000nm, the results of the continuous bending test are not good. Particularly, in Sample 109 not having the third gas barrier layer, and Sample 112 in which the third gas barrier layer does not contain, as a main component, an oxide of a metal that has a lower redox potential than silicon, the results of the continuous bending test are bad.

### EXAMPLE 2

### [Fabrication of Bottom-Emission Type Organic Electroluminescent Element]

Samples 201 to 211 of the bottom-emission type organic EL element having a light-emitting area of 5 cm×5 cm were fabricated by the use of Sample 101, Samples 104 to 106, and Samples 109 to 112 fabricated in Example 1. Note that, in Table 3 described below, there are shown the sample Numbers and their configurations of the gas barrier films used for the organic EL elements of Samples 201 to 211.

### [Fabrication Procedures of Organic EL Element of Samples 201 to 211]

### (Preparation of Gas Barrier Film)

In order to fabricate the organic EL elements of Samples 201 to 211, there were prepared the gas barrier films of Sample 101, Samples 104 to 106, and Samples 109 to 112 in Example 1 described above.

Note that, in the fabrication of the organic EL element of Sample 203, a PET film having a thickness of 75 μm was pasted, as a support film, on the back surface side (surface opposite to the surface where the organic EL element was formed) of the gas barrier film of Sample 101 via an adhesive layer composed of a heat resistive acrylic resin having a thickness of 20 μm, and was then press-bonded by a nip roll, with the result that a gas barrier film with the support film was fabricated. The support film including the adhesive layer was provided during the production steps of the organic EL element, but after the completion of the fabrication of the organic EL element, the film was peeled off.

### (Formation of Under Layer and First Electrode; Samples 202, 203, 210)

The gas barrier film of each sample was fixed onto a base holder of a commercial vacuum vapor deposition apparatus, Compound 118 was placed in the resistive heating boat made of tungsten, and then the base holder and the heating boat were attached to a first vacuum tank of the vacuum vapor deposition apparatus. Furthermore, silver (Ag) was placed in the resistive heating boat made of tungsten, which was then attached to a second vacuum tank of the vacuum vapor deposition apparatus.

Next, after depressurization of the first vacuum tank of the vacuum vapor deposition apparatus up to 4×10⁻⁴ Pa, the heating boat containing Compound 118 was heated by applying an electric current, and then, the under layer of the first electrode having the thickness of 10 nm was provided at a vapor-deposition rate of 0.1 nm/sec to 0.2 nm/sec.

Next, the base obtained by forming layers up to the under layer was transferred to the second vacuum tank under vacuum, and after depressurization of the second vacuum tank up to 4×10⁻⁴ Pa, the heating boat containing silver was heated by applying an electric current. Accordingly, there was formed the first electrode (anode) made of silver having a thickness of 8 nm at a vapor-deposition rate of 0.1 nm/sec to 0.2 nm/sec.

### (Formation of First Electrode; Samples 201, 204 to 209, 211)

A first electrode (anode) was formed on the gas barrier film of each sample by subjecting an ITO film to facing-sputtering under the conditions that a thickness of an ITO film was 15 nm, and under the conditions of Ar 20 sccm, a sputtering pressure 0.5 Pa, room temperature, an electric power on the target side 150 W, and a forming rate 1.4 nm/s. A distance between the target and substrate was 90 mm.

### (Organic Functional Layer to Second Electrode)

Subsequently, after depressurization up to a degree of vacuum of 1×10⁻⁴ Pa by the use of the commercially available vacuum vapor deposition apparatus, Compound HT-1 was deposited at a vapor-deposition rate of 0.1 nm/sec while the base was transported, and thus the positive hole transport layer (HTL) of 20 nm was provided.

Next, the light-emitting layer having the thickness of 70 nm was formed, by the use of Compound A-3 (blue light-emitting dopant), Compound A-1 (green light-emitting dopant), Compound A-2 (red light-emitting dopant) and Compound H-1 (host compound), in such a co-deposition manner that Compound A-3 was deposited by changing the vapor-deposition rate linearly depending on the position so as to have a concentration of 35% by mass to 5% by mass in the direction of thickness, each of Compound A-1 and Compound A-2 was deposited at a vapor-deposition rate of 0.0002 nm/sec so as to have a concentration of 0.2% by mass regardless to the film thickness, and Compound H-1 was deposited by changing the vapor-deposition rate depending on the position so as to have a concentration of 64.6% by mass to 94.6% by mas.

After that, the electron transport layer was formed by deposition of Compound ET-1 having a film thickness of 30 nm, and furthermore, a potassium fluoride (KF) layer was formed in a thickness of 2 nm. Moreover, the second electrode (cathode) was formed by the deposition of aluminum having a thickness of 110 nm.

Note that, Compound 118, Compound HT-1, Compounds A-1 to -3, Compound H-1, and Compound ET-1 are the compounds shown below.

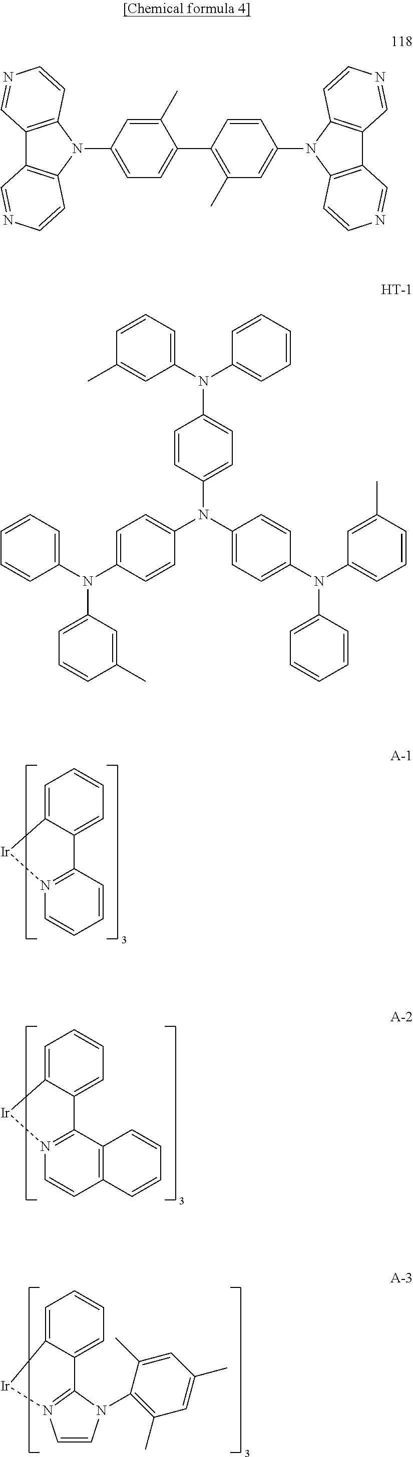

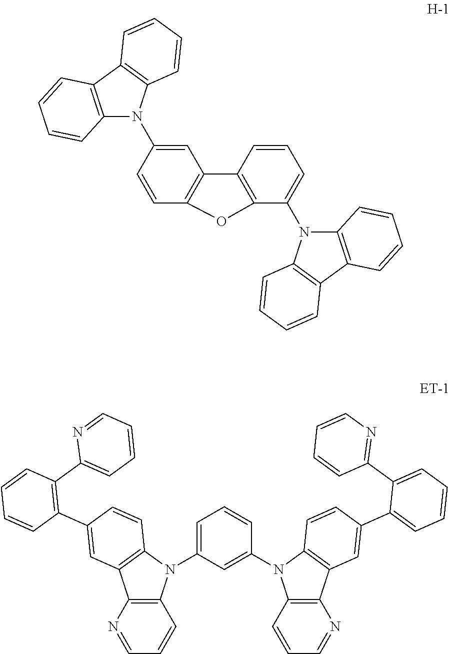 [SMILES: c1cc(-n2c3ccccc3c3ccccc32)c2oc3ccc(-n4c5ccccc5c5ccccc54)cc3c2c1 ; c1ccc(-c2ccccc2-c2ccc3c(c2)c2ncccc2n3-c2cccc(-n3c4ccc(-c5ccccc5-c5ccccn5)cc4c4ncccc43)c2)nc1]

### (Solid Sealing)

Next, an aluminum foil having a thickness of 25 μm was used as a sealing member, and the sealing member obtained by sticking, onto one surface of the aluminum foil, a thermosetting sheet-like adhesive (epoxy-based resin) in a thickness of 20 μm, as a sealing resin layer, was overlapped with the sample obtained by fabricating layers up to the second electrode. At this time, the adhesive-forming surface of the sealing member and the organic functional layer surface of the element were continuously overlapped so that the terminals of the extraction electrodes of the first electrode and the second electrode were exposed outside.

Subsequently, the sample was placed within the reduced pressure apparatus, and was held for 5 minutes by application of a pressure to the resin base and the sealing member which were overlapped, under the reduced pressure condition of 90° C. and 0.1 MPa. Then, after the sample was returned to the atmospheric circumstance, was further heated at 120° C. for 30 minutes, and thus the adhesive was cured.

The above sealing step was performed at a measured cleaning degree of class 100 under a nitrogen atmosphere at an atmospheric pressure and at a water content of 1 ppm or less, in accordance with JIS B 9920:2002, and under an atmospheric pressure of a dew-point temperature of −80° C. or less and an oxygen concentration of 0.8 ppm or less. Note that there is omitted the description as to formation of the extraction wirings from the first electrode and the second electrode, or the like.

### [Evaluation of Organic EL Element]

The following evaluation was carried out as to the fabricated samples of the organic EL element.

### (Continuous Bending Test)

The continuous bending test was conducted by continuous reciprocating bending of the gas barrier film 1,000 times at a curvature of a bending diameter 6 mmφ at room temperature, and the difference in the degrees of degradation between the bent portion and the not bent portion was evaluated on a scale of 1 to 5 [(good) 5>1 (bad)].

### (Bending Storage Test)

Each sample of the organic EL element was stored for 500 hours under the circumstance of 85° C., 85% RH in a state where the element was wound around a roller made of plastics having a curvature of 6 mmφ so that the formation surface of the organic EL element was located outside. After that, light was emitted by application of a current of 1 mA/cm² to each organic EL element removed from the roller. Next, a photograph was taken by magnifying a part of the light-emitting portion of the organic EL element by the use of a 100 time optical microscope (MS-804 manufactured by Moritex Corporation, lens MP-ZE25-200). A photographed image was cut into a 2 mm square part, and then the presence or absence of dark spots was observed for each image. From the results of the observation, a ratio of the dark spot-generating area to the light-emission area was obtained, and then the resistance to dark spots was evaluated according to the following standard.

5: Not observed any dark spot-generation

4: Dark spot-generation area being 0.1% or more and less than 1.0%

3: Dark spot-generation area being 1.0% or more and less than 3.0%

2: Dark spot-generation area being 3.0% or more and less than 6.0%

1: Dark spot-generation area being 6.0% or more

The configurations of the above organic EL elements of Samples 201 to 211 and the respective evaluation results are shown in Table 3.

TABLE 3

| | | | First | | Second | | Third | | | | | |
|---|---|---|---|---|---|---|---|---|---|---|---|---|
| | Gas | | barrier layer | | barrier layer | | barrier layer | | | | | |
| | barrier | Support | Production | Thick- | | Thick- | Compo- | Thick- | | Continuous | Bending | |
| | film | film | method | ness nm | Material | ness nm | sition | ness nm | Anode | bending | storage | |
| 201 | 101 | Absence | Plasma CVD | 200 | PHPS | 470 | Nb₂O₅ | 100 | ITO | 5 | 4 | Present invention |
| 202 | 101 | Absence | Plasma CVD | 200 | PHPS | 470 | Nb₂O₅ | 100 | Ag | 5 | 5 | Present invention |
| 203 | 101 | Presence | Plasma CVD | 200 | PHPS | 470 | Nb₂O₅ | 100 | Ag | 5 | 5 | Present invention |
| 204 | 104 | Absence | Plasma CVD | 200 | PHPS | 470 | Ta₂O₅ | 50 | ITO | 5 | 4 | Present invention |
| 205 | 105 | Absence | Plasma CVD | 200 | PHPS | 470 | TiO₂ | 100 | ITO | 4 | 4 | Present invention |
| 206 | 106 | Absence | Plasma CVD | 200 | PHPS | 470 | ZrO₂ | 100 | ITO | 4 | 4 | Present invention |
| 207 | 109 | Absence | Plasma CVD | 200 | PHPS | 470 | None | — | ITO | 1 | 2 | Comparative Example |
| 208 | 110 | Absence | Plasma CVD | 200 | PHPS | 35 | Nb₂O₅ | 100 | ITO | 3 | 2 | Comparative Example |
| 209 | 111 | Absence | Plasma CVD | 200 | PHPS | 1100 | Nb₂O₅ | 100 | ITO | 3 | 2 | Comparative Example |
| 210 | 111 | Absence | Plasma CVD | 200 | PHPS | 1100 | Nb₂O₅ | 100 | Ag | 3 | 3 | Comparative Example |
| 211 | 112 | Absence | Plasma CVD | 200 | PHPS | 1100 | SiO₂ | 100 | ITO | 1 | 1 | Comparative Example |

As shown in Table 3, Samples 201 to 206 in which the first to third gas barriers satisfy the requirements of the above embodiment are good in the results of both the continuous bending test and the bending storage test. Particularly, Samples 202 and 203 which used the oxide of Nb as the third gas barrier layer and in which the under layer and the thin Ag layer was provided as an anode are good in the results of both the continuous bending test and the bending storage test. It is assumed that, since the oxide of the metal having a low redox potential which constitutes the third gas barrier layer was oxidized earlier than the region (b) of the second gas barrier layer to thereby suppress the lowering of the gas barrier property of the second gas barrier layer, the durability of the gas barrier film in the high temperature and high humidity circumstance is enhanced.

On the other hand, as to Sample 207 in which the third gas barrier layer is not present, and Sample 211 in which the third gas barrier layer is the silicon oxide and does not contain a metal having a lower redox potential than silicon, the obtained results of both the continuous bending test and the bending storage test were bad.

It is assumed that, since Sample 207 and Sample 211 do not have the third gas barrier layer containing, as a main component, an oxide of a metal having a low redox potential, there cannot be suppressed the local lowering of the gas barrier property of the region (b) of the above-described second gas barrier layer, the durability of the gas barrier film in the high temperature and high humidity circumstance is low.

Furthermore, as to Samples 208 to 210 in which the thickness of the region (b) of the second gas barrier layer is outside the range of 50 to 1,000 nm, the results of both the continuous bending test and the bending storage test are degraded in comparison with Samples 201 and 202 having a similar configuration excluding the second gas barrier layer. It is considered that this is caused by the fact that the thickness of the region (b) of the second gas barrier layer is insufficient, or that the modification of the region (b) is insufficient due to the thickness.

Note that the present invention is not limited to the configurations explained in the above exemplary embodiments, and additional various modifications and changes can be made within the scope not departing from the configuration of the present invention.

### REFERENCE SIGNS LIST

1: Resin base

1a, 1b, 1c, 1d, 1e: Base

10: Feeding roll

11, 12a, 12b, 13a, 13b, 14: Conveying roll

15a: First film deposition roll

15b: Third film deposition roll

16a: Second film deposition roll

16b: Fourth film deposition roll

17: Winding roll

18a, 18b: Gas supply pipe

19a, 19b: Power source for generating plasma

20a, 20b, 21a, 21b: Magnetic field-generating device

21: Gas barrier film

22: Gas barrier layer

22a: First gas barrier layer

22b: Second gas barrier layer

22c: Third gas barrier layer

23: First electrode

25: Second electrode

26: Light-emitting unit

27: Sealing layer

28: Sealing member

30: Vacuum chamber

40a, 40b: Vacuum pump

41: Control portion

100, 101: Film deposition apparatus

1. A gas barrier film comprising:
a resin base having a thickness of 3 to 50 μm;
a first gas barrier layer containing an inorganic compound;
a second gas barrier layer that is formed by applying an energy to a coating film obtained by applying and drying a coating liquid containing a polysilazane, and that has a region satisfying a composition range represented by SiO_{w}Nₓ (wherein 0.2<w≦0.55 and 0.66<x≦0.75) and having a thickness of 50 to 1,000 nm; and
a third gas barrier layer that is formed in contact with the second gas barrier layer and that contains, as a main component, an oxide of a metal that has a lower redox potential than silicon.

2. The gas barrier film according to claim 1, wherein the third gas barrier layer contains, as a main component, an oxide of at least one kind of the metal selected from the group consisting of niobium, tantalum, zirconium and titanium.

3. The gas barrier film according to claim 1, wherein the application of the energy is vacuum ultraviolet ray irradiation.

4. An organic electroluminescent element comprising:
a gas barrier film, and
an organic functional layer sandwiched between a first electrode and a second electrode; and
the gas barrier film including,
a resin base having a thickness of 3 to 50 μm;
a first gas barrier layer containing an inorganic compound;
a second gas barrier layer that is formed by applying an energy to a coating film obtained by applying and drying a coating liquid containing a polysilazane, and that has a region satisfying a composition range represented by SiO_{w}Nₓ (wherein 0.2<w≦0.55 and 0.66<x≦0.75) and having a thickness of 50 to 1,000 nm; and
a third gas barrier layer that is formed in contact with the second gas barrier layer and that contains, as a main component, an oxide of a metal that has a lower redox potential than silicon.

5. The organic electroluminescent element according to claim 4, wherein the first electrode is a layer having a thickness of 20 nm or less and containing a silver as a main component.
